(19) United States
(12) Patent Application Publication
(10) Pub. No.: US 2021/0381103 A1
(43) Pub. Date: Dec. 9, 2021

(54) ACTIVATED CARBON MODIFIED BY ATOMIC LAYER DEPOSITION AND METHODS THEREOF

(71) Applicant: Ingevity South Carolina, LLC, North Charleston, SC (US)

(72) Inventors: Paul Pepin, Charleston, SC (US); Kirby Ethridge, North Charleston, SC (US); Cameron Thomson, Charleston, SC (US); Billy-Paul Holbrook, Mount Pleasant, SC (US)

(21) Appl. No.: 17/339,634

(22) Filed: Jun. 4, 2021

Related U.S. Application Data
(60) Provisional application No. 63/035,224, filed on Jun. 5, 2020.

(51) Int. Cl. C23C 16/04; B01J 20/28; B01J 20/20; B01J 20/32; C23C 16/18; C23C 16/455; B01J 20/282

(52) U.S. Cl. CPC C23C 16/045; B01J 20/28064; B01J 20/20; B01J 20/28066; B01J 20/3236; B01J 20/28085; B01J 20/28016; C23C 16/18; C23C 16/45527; B01J 20/282; B01J 20/28083; B01J 20/3214

(57) ABSTRACT

The present description provides structures, atomic layer deposition methods for preparing the structures, and an apparatus preparing the structures. The described structures provide unexpected advantages as compared to currently available materials.

### BACKGROUND

Field of the Discovery. The present disclosure, in various aspects and embodiments, relates to modified activated adsorbent materials, e.g., modified by atomic layer deposition methods, and methods and systems comprising the same.

2. Background Information. For catalytically-driven processes, the rate of reaction is often limited by the number of available active sites on the catalytic substrate. As a result, maximizing surface area is an important design aspect of many heterogeneous catalyst systems. One method frequently used to achieve high surface area is to disperse the catalytically active material (e.g. TiO₂, SiO₂, or Al₂O₃) onto a high surface area support material such as an activated carbon. For example, TiO₂ is an industrially-relevant oxide with wide-ranging applications including as a photocatalyst, catalyst for NOx reduction via selective catalytic reduction (SCR) for stationary power applications, catalyst support for various active metals, pigments and coatings, ceramics, and various consumer products, to name a few.

One commonly employed technique for dispersing a catalytically active material onto a support material is incipient wetness impregnation, whereby the active material is first dissolved in solution, often as a nitrate salt (e.g. Ce(NO₃)₃), and then added to the porous support, where capillary action pulls the solution into the porous structure. Once the pores of the support are filled with the solution, the saturated support is dried and calcined to drive off the volatile species, depositing the active metal onto the walls of the support. Although this technique is relatively effective at dispersing the active material onto the support structure, the technique poses several notable drawbacks. First, particle size is not well-controlled, resulting in a fraction of the active material which cannot be utilized. Additionally, there is often poor contact between the deposited active material and the support material, which commonly results in crystallization and agglomeration of the active phase, leading to further loss of surface area and active material utilization. Similarly, upon heating the active metal particles sinter yielding larger particles lowering the atomic efficiency. Furthermore, only a fraction of the support surface is covered with active material by this technique.

An alternative technique that has been recently explored for dispersing metal particles onto oxide supports is atomic layer deposition (ALD). An advantage of using ALD as compared to conventional catalyst loading of the active metal material onto the support is that ALD allows for depositing metals or metal oxides in a highly dispersed manner, thus improving the atomic efficiency and surface area of the catalytically active metal material. During ALD, the active metal material is introduced onto the support as a vapor. To provide sufficient vapor pressure, the active metal material is typically prepared in organometallic form. Upon exposing the support material to the organometallic vapor, the surface of the support is coated with the organometallic precursor until saturated. Ideally, the conditions under which the organometallic precursor is adsorbed onto the surface will result in the first layer being partially oxidized and strongly adsorbed to the surface. After exposure to the organometallic precursor, the support is purged with an inert species or exposed to vacuum for a period to remove adsorbed multilayer species. At this point, the active metal-coated support is exposed to an oxidant, such as ozone, water, or calcined in air, to fully oxidize the adsorbed organometallic species. This stepwise sequence of introducing the precursor followed by oxidation is referred to as a single ALD cycle. Given that each cycle consists of adsorbing only a monolayer of precursor material, the process is inherently self-limiting, resulting in at most a single atomic layer per cycle.

ALD is commonly used for semiconductor device fabrication and has recently been explored for synthesis of catalytically active materials. In both of these applications, ALD is performed on support or substrate materials having functional groups (e.g., oxygen-containing functional groups) bound to the surface, where the oxygen atoms initiate the ALD growth mechanism by partially oxidizing the adsorbed organometallic species. Conventional methods use carrier gases such as helium to deliver the precursor gases to the substrate and were developed by the semiconductor industry for deposition on relatively flat surfaces, rather than highly porous surfaces used as supports for, for example, heterogeneous catalysts. Because the substrates used in conventional methods for semiconductor fabrication generally have flat surfaces; and therefore, less surface area, the time of exposure of the substrate to the precursor gases is very short, allowing for rapid cycling, but several cycles are often needed because less active metal material is deposited per cycle. Although the number of cycles required to modify the surface of porous (i.e., relatively high surface area) materials is much less than for planar semiconductor materials to achieve similar loading, diffusion of precursor and oxidant through the porous material limits the rate at which cycling can be performed.

Because diffusion of the precursor gases in and out of the pores of the porous substrate materials is slow, using a carrier gas as is used in conventional methods is impractical as the precursor gases are blown through the system and not recovered, leading to increased costs. Therefore, there is a need in the art for catalytically active porous materials and improved methods of their production.

### SUMMARY

Presently described are porous structures and methods of making the same. Surprisingly and unexpectedly, it was discovered that porous materials, for example, as activated adsorbent materials, such as activated carbon, can serve as substrates for ALD.

Thus, in one aspect the description provides a structure comprising an activated adsorbent material, e.g., porous activated adsorbent material, and a metal species deposited thereon. In certain aspects, the description also provides a structure comprising a substrate including an activated adsorbent material and a metal species deposited thereon.

In an additional aspect, the description provides a method for preparing a structure according to the steps comprising: (a) providing an activated adsorbent material, e.g., a porous activated adsorbent material, for example, activated carbon, in a reactor; (b) administering or performing at least one atomic layer deposition cycle to deposit a metal species, e.g., a metal oxide, wherein the at least one atomic layer deposition cycle comprises: (i) introducing a first precursor gas into the reactor to provide a metal species precursor; and (ii) introducing a second precursor gas into the reactor to provide the structure. In any aspect or embodiment, step (b) is repeated from 2 to about 10 times.

In an additional aspect, the description provides a structure prepared by atomic layer deposition (ALD) according to the steps comprising: (a) providing an activated adsorbent material, e.g., a porous activated adsorbent material, for example, activated carbon, in a reactor; (b) administering at least one atomic layer deposition (ALD) cycle to deposit a metal species, e.g., a metal oxide, wherein the at least one atomic layer deposition cycle comprises: (i) introducing a first precursor gas into the reactor to provide a metal species precursor; and (ii) introducing a second precursor gas into the reactor to provide the structure.

In any aspect or embodiment described herein, the structure prepared by atomic layer deposition (ALD) is a porous, metal-coated structure.

In any aspect or embodiment described herein, the activated adsorbent material is a porous activated adsorbent material. In any aspect or embodiment described herein, the porous activated adsorbent material comprises activated carbon, e.g., porous activated carbon. In any aspect or embodiment described herein, the activated carbon comprises an activated carbon powder, granular, pellet, monolith or honeycomb form.

In any of the aspects or embodiments described herein, the metal species includes at least one metal. The metal species may be derived from a metal species precursor having at least one metal and at least one ligand, which may be subsequently synthetically modified (e.g., oxidized or reduced) to provide the metal species.

The preceding general areas of utility are given by way of example only and are not intended to be limiting on the scope of the present disclosure and appended claims. Additional objects and advantages associated with the compositions, methods, and processes of the present invention will be appreciated by one of ordinary skill in the art in light of the instant claims, description, and examples. For example, the various aspects and embodiments of the invention may be utilized in numerous combinations, all of which are expressly contemplated by the present description. These additional advantages objects and embodiments are expressly included within the scope of the present invention. The publications and other materials used herein to illuminate the background of the invention, and in particular cases, to provide additional details respecting the practice, are incorporated by reference.

### BRIEF DESCRIPTION OF THE DRAWINGS

The accompanying drawings, which are incorporated into and form a part of the specification, illustrate several embodiments of the present invention and, together with the description, serve to explain the principles of the invention. The drawings are only for the purpose of illustrating an embodiment of the invention and are not to be construed as limiting the invention. Further objects, features and advantages of the invention will become apparent from the following detailed description taken in conjunction with the accompanying figures showing illustrative embodiments of the invention, in which:

FIG. 1 shows an exemplary embodiment of an apparatus used for the ALD methods.

FIG. 2 shows the results of the gravimetric analysis of the activated carbon powder modified with titanium oxide after 1-4 cycles of ALD.

FIGS. 3A-3D show the wt % TiO₂ for activated carbon powder modified with titanium oxide after 0 cycles ALD (FIG. 3A), 1 cycle (FIG. 3B), 2 cycles (FIG. 3C), and 4 cycles (FIG. 3D).

FIGS. 4A-4D are scanning electron microscopy (SEM) images of the activated carbon powder modified with titanium oxide after 0 cycles ALD (FIG. 4A), 1 cycle (FIG. 4B), 2 cycles (FIG. 4C), and 4 cycles (FIG. 4D).

FIG. 5 shows the TiO₂ growth rate through 4 ALD cycles for the activated carbon powder modified with titanium oxide.

FIGS. 6A-6C show the 2-propanol temperature programmed desorption (TPD) spectra of unmodified activated carbon powder (FIG. 6A), activated carbon powder modified with titanium oxide (FIG. 6B), and P25 TiO₂ (FIG. 6C).

FIGS. 7A-7B show the product spectra comparison for acetone (FIG. 7A) and propene (FIG. 7B) from the 2-propanol TPD of activated carbon powder modified with titanium oxide and P25 TiO₂.

FIG. 8 shows an exemplary embodiment of an apparatus used for the ALD methods.

FIGS. 9A-9C show SEM images of virgin commercially available carbons WV-A1100 (FIG. 9A), BAX1500 (FIG. 9B), and synthetic graphite (FIG. 9C).

FIG. 10 shows a comparison of the XPS spectra for AG (AQUAGUARD), oxidized RGC, Oxidized graphite, graphite, RGC, WV-A1100, and BAX 1500 carbons.

FIG. 11 shows a comparison of the estimated surface coverage for coconut, oxidized RGC, RGC, WV-A1100, AG (AQUAGUARD), and graphite. This figure shows that the rate of TiO₂ ALD was greatest for coconut and follows the order: coconut>Oxidized RGC>Aquaguard>WV-A1100>RGC>graphite.

FIGS. 12A-12F shows the SEM images of oxidized RGC, AG, and graphite after two cycles of TiO₂ ALD in the upper panel and corresponding XRD spectra in the lower panel.

FIG. 13 shows the XPS spectrum of WV-A 1100 before and after TiO₂ ALD. The virgin material is the bottom trace, the material after one cycle of ALD is the middle trace and the material after two cycles of ALD is the top trace.

FIG. 14 shows the XPS spectra of coconut, WV-A 1100, and RGC, each after two cycles of TiO₂ ALD. The RGC after two cycles of ALD is the bottom trace, the 1100 after two cycles of ALD is the next highest trace, and coconut after two cycles of ALD is the top trace.

FIG. 15 shows the pore size distribution (PSD) of WV-A1100 before and after TiO₂ ALD. The virgin material is the top trace, the material after one cycle of ALD is the middle trace and the material after two cycles of ALD is the bottom trace.

FIGS. 16A-16B show the TPD spectra after two cycles of TiO₂-ALD for WV-A1100 and RGC, respectively. For each of FIGS. 16A-16B, the spectrum of the ALD-modified material is overlayed with that of the virgin material. The lower curves for 2-propanol, acetone and propene are for the virgin material and the upper curve for each of 2-propanol, acetone, and propene after a 2 cycles of ALD.

FIG. 17 shows the TPD spectrum of TiO₂-modified graphite.

FIG. 18 shows the TPD spectrum of TiO₂-modified AQUAGUARD.

FIG. 19 shows the TPD spectrum of TiO₂-modified oxidized RGC.

FIGS. 20A-20F shows the SEM photographs and XRD of WV-A 1100 after one cycle of Pd ALD (FIGS. 20A-20B), two cycles of ALD (FIGS. 20C-20D), and four cycles of ALD (FIGS. 20E-20F).

FIG. 21 shows the XPS of Pd-modified samples of WV-A 1100 after 1, 2, and 4 cycles of ALD. The bottom trace is the virgin material, the next trace above is after 1 cycle of ALD, the next trace above is after 2 cycles of ALD, and the top trace is after 4 cycles of ALD. The peak at 335.8 corresponds to Pd(0).

FIG. 22 shows the wt % of Pd deposited on WV-A 1100 after 1 cycle (1.29 wt %), 2 cycles (2.84 wt %), and 4 cycles (5.21 wt %) of ALD.

FIG. 23 shows the disappearance of abietic acid over time when abietic acid is subjected to a disproportionation reaction. The two overlapping curves are the reaction without catalyst and with the virgin material. The bottom curve corresponds to the reaction of abietic acid in the presence of the Pd-modified material (i.e., catalyst) obtained after 1 and 2 cycles of ALD. The curve above that corresponds to the reaction of abietic acid in the presence of the Pd-modified material (i.e., catalyst) obtained after 1 cycle of ALD.

FIG. 24A shows the TGA spectrum using air and N2 of the product from the alcohol dehydrogenation reaction of 2-propanol in the presence of Pd deposited on WV-A 1100 catalyst.

FIG. 24B shows the evolved gas TPD spectrum from the reaction.

FIG. 25A shows SEM images of graphite after 2 cycles of Pd ALD at 10,000× magnification. FIG. 25B shows SEM photographs of graphite after 2 cycles of Pd ALD at 100,000× magnification.

FIG. 26A shows SEM images of oxidized graphite after 2 cycles of Pd ALD at 10,000× magnification. FIG. 26B shows SEM images of graphite after 2 cycles of Pd ALD at 100,000× magnification.

FIGS. 27A-27B shows the XPS of graphite and oxidized graphite before and after 2 cycles of ALD. In FIG. 27A, the bottom trace is the virgin graphite and the trace above is after the second cycle of ALD; above that is the virgin oxidized graphite and the trace above is after the second cycle of ALD. FIG. 27B shows that there is no peak in the region corresponding to Pd.

### DETAILED DESCRIPTION

The present disclosure now will be described more fully hereinafter, but not all embodiments of the disclosure are shown. While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular structure or material to the teachings of the disclosure without departing from the essential scope thereof.

The drawings accompanying the application are for illustrative purposes only. They are not intended to limit the embodiments of the present application. Additionally, the drawings are not drawn to scale. Elements common between figures may retain the same numerical designation.

Where a range of values is provided, it is understood that each intervening value between the upper and lower limit of that range and any other stated or intervening value in that stated range is encompassed within the invention. The upper and lower limits of these smaller ranges may independently be included in the smaller ranges is also encompassed within the invention, subject to any specifically excluded limit in the stated range. Where the stated range includes one or both of the limits, ranges excluding either both of those included limits are also included in the invention.

The following terms are used to describe the present invention. In instances where a term is not specifically defined herein, that term is given an art-recognized meaning by those of ordinary skill applying that term in context to its use in describing the present invention.

The articles “a” and “an” as used herein and in the appended claims are used herein to refer to one or to more than one (i.e., to at least one) of the grammatical object of the article unless the context clearly indicates otherwise. By way of example, “an element” means one element or more than one element.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.”

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the 10 United States Patent Office Manual of Patent Examining Procedures, Section 2111.03.

As used herein in the specification and in the claims, the phrase “at least one,” in reference to a list of one or more elements, should be understood to mean at least one element selected from anyone or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a nonlimiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc. It should also be understood that, unless clearly indicated to the contrary, in any methods claimed herein that include more than one step or act, the order of the steps or acts of the method is not necessarily limited to the order in which the steps or acts of the method are recited.

As used herein, the terms “fluid,” “gas” or “gaseous” and “vapor” or “vaporous” are used in a general sense and, unless the context indicates otherwise, are intended to be interchangeable.

ALD methods wherein the precursor gas is chemisorbed onto the surface of the substrate require the presence of functional groups (e.g., oxide species) on the surface of the substrate capable of reacting with the precursor gas to displace the ligands of the precursor gas. Typically, it is desirable to have sufficient adsorption site density (number of surface functional groups per unit area) on the surface of the substrate to provide uniform monolayer coverage of the substrate. For example, a silicon wafer, which is commonly used in semiconductor fabrication, has silanol groups homogeneously and uniformly covering the surface such that when ALD is used to apply a metal oxide coating, because of the high number of surface silanol groups, saturation of the surface of the silicon wafer substrate with the ALD layer is expected.

In the case of porous carbon-based substrates such as activated carbon, the surface is heterogeneous and the site density of these functional groups is nonuniform and expected to be less than the adsorption site density for commonly-used substrates such as silicon wafers so that precursor chemisorption and partial oxidation for ALD growth is unexpected. Thus, to achieve ALD on many carbon-based materials, the surfaces of the carbon-based materials must first be pretreated to modify their surface chemistry. For example, it has been demonstrated that ALD can be used to coat carbon nanotubes (CNTs) but the carbon material requires surface modification prior to the ALD process. Surface functionalization of CNTs is often employed to increase steric hindrance between adjacent CNTs to facilitate exfoliation and improve solubility. Surface functionalization also potentially offer sites for ALD. Conventional examples of CNT surface modification include chemical agents for surface oxidation, annealing with plasma or non-covalently attached groups such as surfactants, polymers, or DNA. Another conventional method for surface modification includes depositing metal seeds on the surface by physical vapor deposition. Yet another conventional method used for surface modification of CNTs is treatment with diazonium salts to add aryl or aliphatic groups to their surface. Diazonium salts have also been used to functionalize porous carbon materials, e.g., activated carbon. U.S. Pat. No. 7,698,191 teaches the use of diazonium salt chemistry on carbon materials in order to provide organic functional groups. The surface-bound organic functional group enables metal deposition on carbon materials via ALD processes. Using diazonium salts is an effective means of controlling the extent and nature of surface functionality; however, the functionality that can be added by this technique is limited mainly to organic species. While the addition of a functional group such as by diazonium salt treatment is beneficial for exfoliation of CNTs and may also provide functionality for ALD, the added steric hindrance posed by the addition of a functional group on a porous substrate can lead to loss in pore volume even before ALD. This additional processing step also poses added complexity and decreased atomic efficiency in the preparation of the substrate, as well as the added process safety risks posed by many diazonium salts. Therefore, it was surprisingly and unexpectedly discovered that a non-uniform, porous activated adsorbent material, e.g., activated carbon, could be modified with a metal oxide using ALD methods without the use of a surface pretreatment to modify surface chemistry or add surface functional groups. Therefore, in any of the aspects or embodiments, the description provides processes and methods that, aside from activation, excludes any additional step of treating a substrate comprising an activated adsorbent material to modify surface chemistry or add surface functional groups

Presently described is a structure that surprisingly and unexpectedly demonstrates that activated adsorbent materials such as activated carbon could serve as substrates for ALD. ALD methods wherein the precursor gas is chemisorbed onto the surface of the substrate require the presence of functional groups (i.e., oxide species) on the surface of the substrate capable of reacting with the precursor gas to displace a ligand. Typically, it is desirable to have sufficient adsorption site density on the surface of the substrate to provide uniform monolayer coverage of the substrate. However, in the case of an adsorbent material such as activated carbon, the adsorption site density may be lower than the adsorption site density for commonly-used substrates, such as silicon wafers, used in ALD methods in the semiconductor industry. Because the adsorption site density may be lower for activated carbon, the substrate surface with the metal species may not be saturated and the layer may not be uniform. Therefore, it was surprisingly and unexpectedly discovered that an adsorbent material such as activated carbon could be modified with a metal species such as metal oxide using ALD methods.

Thus, in any aspect or embodiment, the description provides a structure comprising an activated adsorbent material, e.g., a porous activated adsorbent material, and a metal species deposited thereon. In certain aspects or embodiments, the description also provides a structure comprising: a substrate including an activated adsorbent material, e.g., a porous activated adsorbent material, and a metal species deposited thereon.

As used herein, unless the context indicates otherwise, the term “substrate (or material) comprising (or including) an activated adsorbent material” can mean a substrate or material comprising between 1-100 wt % (e.g., at least about 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, 52, 53, 54, 55, 56, 57, 58, 59, 60, 61, 62, 63, 64, 65, 66, 67, 68, 69, 70, 71, 72, 73, 74, 75, 76, 77, 78, 79, 80, 81, 82, 83, 84, 85, 86, 87, 88, 89, 90, 91, 92, 93, 94, 95, 96, 97, 98, 99 or 100 wt %, including all ranges and sub-ranges in between) of an activated adsorbent material, e.g., a porous activated adsorbent material as described herein. For example, where the substrate or material includes less than 100 wt % of activated adsorbent material, the balance up to 100 wt % can include one or more additives known in the art, such as by non-limiting example, binder, processing aid or the like.

When the at metal species includes titanium oxide, the structure surprisingly and unexpectedly demonstrates superior catalytic activity as compared to commonly-used titanium oxide nanoparticles, for example, those commercially available as P25 TiO₂ (Evonik).

In any of the aspects or embodiments described herein, the substrate of the structure includes an activated adsorbent material. The activated adsorbent material includes activated carbon, carbon charcoal, zeolites, clays, porous polymers, foams, porous alumina, porous silica, molecular sieves, kaolin, titania, ceria, or combinations thereof. In any of the aspects or embodiments described herein, the activated adsorbent material is activated carbon. The activated adsorbent material can be derived from an activated adsorbent material precursor. By way of non-limiting example, the activated adsorbent material precursors may be wood, wood dust, wood flour, cotton linters, peat, coal, coconut, lignite, carbohydrates, petroleum pitch, petroleum coke, coal tar pitch, fruit pits, fruit stones, nut shells, nut pits, sawdust, palm, vegetables such as rice hull or straw, synthetic polymer, natural polymer, lignocellulosic material, or combinations thereof. Furthermore, the activated adsorbent material may be produced using a variety of processes including, but are not limited to, chemical activation, thermal activation, or combinations thereof.

In any of the aspects or embodiments described herein, the activated adsorbent material comprises activated carbon powder. Activated carbon has been processed to make it highly porous (i.e., having a large number of pores per unit volume), which imparts a high surface area. In any of the aspects or embodiments described herein, the surface of the activated adsorbent material of the substrate has not been modified prior to deposition of the metal species using, for example, ALD. As used herein, “modification” of the surface of the activated adsorbent material excludes the activation process. The activated adsorbent material can be prepared using an activation process. In any of the aspects or embodiments described herein, the activated adsorbent material is an activated carbon. Native carbon (non-activated carbon) can be activated using an activating agent comprising at least one of phosphoric acid, sulfuric acid, boric acid, nitric acid, oxygenated acids, steam, air, peroxides, alkali hydroxides, metal chlorides, ammonia, carbon dioxide, or a combination thereof. Activation conditions including temperature and pressure are within the skill of one of ordinary skill in the art. As used herein, “modification” includes reaction with diazonium salts to add aryl or aliphatic group linkers to the surface substituted with functional groups. In any of the aspects or embodiments described herein, the surface of the activated adsorbent material has not been modified by reaction with diazonium salts to add functionalized aryl or aliphatic group linker groups bound to the surface.

In any of the aspects or embodiments described herein, the activated carbon can be derived from an activated carbon precursor. Activated carbons may be generated from a variety of materials, however most commercially available activated carbons are made from peat, coal, lignite, wood, and coconut shells. Based on the source, the carbon can have different pore sizes, ash content, surface order, and/or impurity profiles. Coconut shell-based carbon has predominantly a microporous pore size, whereas a wood-based chemically activated carbon has a predominately mesoporous or macroporous pore size. In a preferred embodiment, the activated carbon comprises an activated carbon powder. By way of non-limiting example, the activated carbon precursors may be wood, wood dust, wood flour, cotton linters, peat, coal, coconut, lignite, carbohydrates, petroleum pitch, petroleum coke, coal tar pitch, fruit pits, fruit stones, nut shells, nut pits, sawdust, palm, vegetables such as rice hull or straw, synthetic polymer, natural polymer, lignocellulosic material, or combinations thereof. Furthermore, activated carbon may be produced using a variety of processes including, but are not limited to, chemical activation, thermal activation, or combinations thereof.

In any of the aspects or embodiments described herein, the activated carbon precursor is wood. The activated carbon precursor can be activated by heating the activated carbon precursor and treating with added oxidizing agents, such as exogenously added activating (i.e., oxidizing) agents, such as carbon dioxide, oxygen, acids or superheated steam. An exemplary activated carbon includes NUCHAR® (Ingevity South Carolina, LLC, SC, USA), which is chemically activated carbon derived from wood and activated with phosphoric acid.

Generally, the larger the surface area of the activated carbon, the greater its adsorption capacity. For example, the available surface area of activated carbon is dependent on its pore volume. Since the surface area per unit volume decreases as individual pore size increases, large surface area generally is maximized by maximizing the number of pores of very small dimensions and/or minimizing the number of pores of very large dimensions. Pore sizes are defined herein as micropores (pore width <2.0 nm), mesopores (pore width=2.0-50 nm), and macropores (pore width >50 nm, and nominally 50 nm-100 micrometers). Mesopores may be further divided between small mesopores (pore width=2.0-5 nm) and large mesopores (pore width=5-50 nm).

The Brunauer-Emmet-Teller (B.E.T.) surface can characterize the specific surface area of a material. Preferably, the activated adsorbent material (e.g., activated carbon) has a nitrogen B.E.T. surface area from about 600 to about 2300, from about 800 to about 1800, or from about 1000 to about 1600 m2 per gram. Surface areas were measured by nitrogen physisorption using the Brunauer-Emmet-Teller (BET) method according to ISO 9277:2010 in a Micromeritics ASAP 2420 (Norcross, Ga.). Pore volumes were determined by nitrogen adsorption porosimetry using a Micromeritics ASAP 2420 (Norcross, Ga.). Briefly, example/samples are dried overnight in an oven preset to 105-110° C. Samples are removed and contained in a closed system until temperature has come to equilibrium with the laboratory. The sample is inserted into the instrument sample tube and placed on a Micromeritics ASAP 2420 instrument. Samples are degassed in situ prior to starting the test. Degassing of the sample is conducted at 250° C. and a vacuum of 2 μmHg. Pore volumes are calculated from the P/Po isotherm curve using the SAIEUS program. The non-ideality factor was 0.0000620. The density conversion factor was 0.0015468. The hard-sphere diameter was 3.860 Å. The molecular cross-sectional area was 0.162 nm2. Target relative pressures (in mmHg) for the isotherm were the following: 0.002, 0.005, 0.01, 0.0125, 0.0250, 0.050, 0.075, 0.1, 0.1125, 0.125, 0.150, 0.175, 0.20, 0.25, 0.30, 0.40, 0.45, 0.50, 0.55, 0.60, 0.65, 0.70, 0.75, 0.80, 0.85, 0.90, and 0.95. At low pressures the equipment is set to “Low Pressure incremental dose mode” which instructs the instrument to record data based on incremental dosages in the amount of 20.0000 cm3/g STP. Actual points were recorded within an absolute or relative pressure tolerance of 5 mmHg or 5% respectively, whichever was more stringent. Time between successive pressure readings was during equilibration was 20 s. When the ΔP between readings was <0.001%, the data was taken and P was set to the next setpoint. Minimum time delay between recording data was 600 seconds. The nitrogen adsorption isotherm data was analyzed by the SAIEUS program. The “Max” field of pore size range is changed to 500. On the L-curve chart, Lambda value is set by scrolling the bar to locate the tangent point on the curve. The mathematical model to process the isotherm data garnered by the Micromeritics instrument to determine pore size distribution is described as nonlocal density functional theory (NLDFT). This model appears to minimize error associated at the low pressure range (equating to small pores), noted in J. Phys. Chem., 2009, 113, 19382-19385 by J. Jagiello and J. P. Olivier.

As previously discussed, In any of the aspects or embodiments described herein, other than activation, the activated adsorbent material is not additionally modified. Modification of a substrate surface can introduce additional surface functional groups, such that there is an increased number of functional groups that are covalently attached to the adsorbent material and capable of binding the metal species. Alternatively, modification of a substrate surface can include a coating of a material (e.g., surfactants) capable of binding the metal species. Therefore, modification of the substrate surface can increase the adsorption site density of the surface. A surface of the activated adsorbent material wherein the surface has not been further modified after activation can have a lower adsorption site density than a surface of an activated adsorbent material that has undergone further surface modification after activation. The ratios of heteroatoms such as oxygen, nitrogen, and phosphorous to carbon can be proportional to the adsorption site density of a surface of an activated adsorbent material.

One method for measuring adsorption site density is surface elemental analysis. Surface analysis techniques can provide information about the chemical composition of the material surface, depending on the analytical method used. The density of elements (e.g., O, N, and P) may be measured using Boehm titration or Auger electron spectroscopy (AES), for example.

Another way to measure adsorption site density is bulk elemental analysis within a specified sampling depth from the surface. X-ray photoelectron spectroscopy (XPS) can be used at a sampling depth of less than or equal to about 5 nm, or less than or equal to about 4 nm, or less than or equal to about 3 nm, or less than or equal to about 2 nm, or less than or equal to about 1 nm. XPS, was conducted to obtain concentrations of carbon, chlorine, fluorine, sodium, nitrogen, oxygen, phosphorous, titanium and palladium by sprinkling the sample powder onto double-sticky tape and removing excess prior to introducing to the vacuum chamber. The data were acquired from an analyzed area having a diameter of ca. 1 mm using a monochromatic Al Kα x-ray source and a 650 take-off angle. Low energy resolution survey scans were obtained from each sample to determine what elements were present. The atomic concentrations of these elements and their local chemistries were determined from higher energy resolution multiplex scans.

In any of the aspects or embodiments described herein, the bulk oxygen to carbon ratio at a sampling depth of less than or equal to about 5 nm is less than or equal to about 0.25, less than or equal to about 0.20, less than or equal to about 0.15, less than or equal to about 0.10, less than or equal to about 0.09, less than or equal to about 0.08, less than or equal to about 0.07, less than or equal to about 0.06, less than or equal to about 0.05, from about 0.01 to about 0.25, from about 0.01 to about 0.25, from about 0.01 to about 0.20, from about 0.01 to about 0.15, or from about 0.01 to about 0.10, including all overlapping ranges, subsumed ranges and values in between.

In any of the aspects or embodiments described herein, the bulk phosphorous to carbon ratio at a sampling depth of less than or equal to about 5 nm is less than or equal to about 0.10, about 0.09, about 0.08, about 0.07, about 0.06, about 0.05, including all overlapping ranges, subsumed ranges and values in between.

In any of the aspects or embodiments described herein, the bulk nitrogen to carbon ratio at a sampling depth of less than or equal to about 5 nm is less than or equal to about 0.10, about 0.09, about 0.08, about 0.07, about 0.06, or about 0.05, including all overlapping ranges, subsumed ranges and values in between.

As used herein, a “surface oxygen to carbon ratio” refers to a ratio of surface carbons that are attached to an oxygen to the total number of surface carbons. The total number of surface carbons is inclusive of unbound surface carbons, carbons attached to oxygen, and carbons attached to other elements or groups. In any of the aspects or embodiments described herein, the surface oxygen to carbon ratio is less than about 1.0, less than about 0.95, less than about 0.90, less than about 0.85, less than about 0.80, less than about 0.75, less than about 0.70, less than about 0.65, less than about 0.60, less than about 0.55, less than about 0.50, less than about 0.45, less than about 0.40, less than about 0.35, less than about 0.30, less than about 0.25, less than about 0.20, less than about 0.15, less about 0.10, from about 0.01 to less than about 1.0, from about 0.10 to less than about 1.0, from about 0.05 to less than about 1.0, from about 0.01 to about 0.95, from about 0.01 to about 0.90, from about 0.01 to about 0.85, from about 0.01 to about 0.80, from about 0.01 to about 0.75, from about 0.01 to about 0.70, from about 0.01 to about 0.65, from about 0.01 to about 0.60, from about 0.01 to about 0.55, from about 0.01 to about 0.50, from about 0.01 to about 0.45, from about 0.01 to about 0.40, from about 0.01 to about 0.35, from about 0.01 to about 0.30, from about 0.01 to about 0.25, from about 0.01 to about 0.20, including all overlapping ranges, subsumed ranges and values in between.

As used herein, a “surface phosphorous to carbon ratio” refers to a ratio of surface carbons that are attached to a phosphorous to the total number of surface carbons. The total number of surface carbons is inclusive of unbound surface carbons, carbons attached to phosphorous, and carbons attached to other elements or groups. It is understood that surface phosphorous can be attached to the surface carbon via a heteroatom linker (e.g., oxygen). The surface phosphorous can exist in an oxidized state or a non-oxidized state. In any of the aspects or embodiments described herein, the surface phosphorous to carbon ratio is less than or equal to about 0.33, about 0.30, about 0.25, about 0.20, about 0.15, or about 0.10, including all overlapping ranges, subsumed ranges and values in between.

As used herein, a “surface nitrogen to carbon ratio” refers to a ratio of surface carbons that are attached to a nitrogen to the total number of surface carbons. The total number of surface carbons is inclusive of unbound surface carbons, carbons attached to nitrogen, and carbons attached to other elements or groups. In any of the aspects or embodiments described herein, the surface nitrogen to carbon ratio is less than or equal to about 0.50, about 0.45, about 0.40, about 0.35, about 0.30, about 0.25, about 0.20, or about 0.10, including all overlapping ranges, subsumed ranges and values in between.

As used herein, a “surface oxygen of oxidized phosphorous to phosphorous ratio” refers to a ratio of surface phosphorous atoms that have been oxidized to the total number of surface phosphorous atoms. The total number of surface phosphorous atoms is inclusive of oxidized and non-oxidized phosphorous atoms. In any of the aspects or embodiments described herein, the surface oxygen of oxidized phosphorous to phosphorous ratio is less than about 1.0, less than about 0.95, less than about 0.90, less than about 0.85, less than about 0.80, less than about 0.75, less than about 0.70, less than about 0.65, less than about 0.60, less than about 0.55, less than about 0.50, less than about 0.45, less than about 0.40, less than about 0.35, less than about 0.30, less than about 0.25, less than about 0.20, less than about 0.15, less about 0.10, from about 0.01 to less than about 1.0, from about 0.10 to less than about 1.0, from about 0.05 to less than about 1.0, from about 0.01 to about 0.95, from about 0.01 to about 0.90, from about 0.01 to about 0.85, from about 0.01 to about 0.80, from about 0.01 to about 0.75, from about 0.01 to about 0.70, from about 0.01 to about 0.65, from about 0.01 to about 0.60, from about 0.01 to about 0.55, from about 0.01 to about 0.50, from about 0.01 to about 0.45, from about 0.01 to about 0.40, from about 0.01 to about 0.35, from about 0.01 to about 0.30, from about 0.01 to about 0.25, from about 0.01 to about 0.20, including all overlapping ranges, subsumed ranges and values in between.

The structure includes a metal species deposited on the substrate including the activated adsorbent material. The metal species can be derived from a metal species precursor. The metal species precursor can include at least one metal and at least one ligand. The metal species precursor can include at least one metal and at least one ligand capable of being displaced and wherein the metal can form a bond with a functional group on the surface of the activated adsorbent material. The metal species can include a single metal or a plurality of metals. The metal species can include metals such as Li, Be, Mg, Ca, Sr, Ba, Sc, Y, La, Ti, Zr, Hf, Ce, V, Nb, Ta, Pr, Cr, Mo, W, Nd, Mn, Fe, Ru, Sm, Co, Rh, Ir, Ni, Pd, Pt, Gd, Cu, Ag, Zn, Cd, B, Al, Ga, In, Si, Sn, Pb, P, Sb, and Bi; metal oxides, such as titanium oxide, copper oxide, cerium oxide, phosphorous oxide, hafnium oxide, aluminum oxide, zirconium oxide, zinc oxide, silicon oxide, tantalum oxide, tungsten oxide, and vanadium oxide; perovskites having the formula, for example, ABO₃, such as CaTiO₃; metal oxide phosphates or metal phosphates, such as vanadium phosphorous oxide (VPO), FePO₄, and silica phosphorous acid; multimetal oxides, such as molybdates, tungstates, antimonates, and vanadates; noble metals and noble metal compounds such as Ru, Pt, Pd, PdO; metal sulfides, metal nitrides, metal phosphides, organometallic compounds, such as metal alkyl compounds, cyclopentadienyl compounds, and metallocenes (e.g., Al(CH₃)₃, MeCpPtMe₃, ferrocene), or any combination thereof. In any of the aspects or embodiments described herein, the metal precursor includes palladium hexafluoro-acetylacetonate or bis(2,2,6,6-tetramethyl-3,5-heptanedionato)palladium(II).

The metal species deposited on the surface of the activated adsorbent material can be in the form of a layer or a coating. As used herein, the terms “film,” “layer,” and “coating” are inclusive of partial films, layers or coatings (i.e., incomplete or not contiguous or uniform), as well as complete films, layers, or coatings (i.e., contiguous). The layer including the metal species can be disposed directly on the surface of the substrate with no intervening layers. The structure can include a single layer or multiple layers. In any of the aspects or embodiments described herein, the structure includes 0 to 10 layers, 1 to 10 layers, 0 to 5 layers, 1 to 5 layers, 2 to 10 layers, 2 to 8 layers, 2 to 5 layers, or 2 to 4 layers.

The structure can include from about 0.1 to about 50 wt %, or about 0.5 to about 50 wt % of the metal of the metal species, based on the total weight of the structure. The structure can include from about 0.5 to about 45 wt %, about 0.5 to about 40 wt %, about 0.5 to about 35 wt %, about 0.5 to about 30 wt %, about 0.5 to about 25 wt %, about 0.5 to about 20 wt %, about 0.5 to about 15 wt %, about 0.5 to about 10 wt %, about 0.5 to about 5 wt % of the metal of the metal species, based on the total weight of the structure. In any of the aspects or embodiments described herein, when the structure includes titanium (IV) oxide as the metal species, the structure includes from about 0.5 to about 50 wt % titanium, based on the total weight of the structure.

The structure is not limited to any application. Non-limiting examples of applications for the structures disclosed herein include catalytic, filtration, antimicrobial, antifungal, photovoltaic, antifungal, chemisorption, antiviral, fabrics, ceramics, biotechnology, biomedical, fuel cell systems, semiconductors, micro-electronics, optics, and gas storage applications.

In an additional aspect, the description is of a structure prepared by an atomic layer deposition (ALD) method according to the steps comprising: (a) providing a substrate comprising an activated adsorbent material, e.g., a porous activated adsorbent material, for example, activated carbon, in a reactor; (b) administering or performing at least one atomic layer deposition cycle to deposit a metal species, e.g., a metal oxide, wherein the at least one atomic layer deposition cycle comprises: (i) introducing a first precursor gas into the reactor to provide a metal species precursor deposited on a surface of the activated adsorbent material; and (ii) introducing a second precursor gas into the reactor to provide the structure. In any aspect or embodiment, step (b) is repeated from 2 to about 10 times.

In any aspect or embodiment described herein, the structure prepared by atomic layer deposition (ALD) is a porous, metal-coated structure.

The first precursor gas can include at least one metal and at least one ligand. The at least one ligand can be capable of being displaced by a surface functional group of the activated adsorbent material. The at least one ligand can be capable of being displaced by an atom provided by the second precursor gas (e.g., O, H). In any of the aspects or embodiments described herein, the first precursor gas includes a metal halide, a metal oxyhalide, a metal alkoxide, an organometallic compound, such as metal alkyl compounds (e.g., Al(CH3)₃), metal alkene compounds, metal alkyne compounds, cyclopentadienyl compounds (e.g., MeCpPtMe3), and metallocenes (e.g., ferrocene), hexafluoro-acetylacetonate, or a combination thereof. In any of the aspects or embodiments described herein, the first precursor gas includes titanium chloride, titanium oxychloride, titanium alkoxide, or a combination thereof. In any of the aspects or embodiments described herein, the first precursor gas includes hexafluoro-acetylacetonate.

The second precursor gas is able to displace at least one ligand of the metal species precursor deposited on the surface of the activated adsorbent material (e.g., oxidation, reduction). The second precursor gas can include a nitrogen-containing precursor gas, such as ammonia, 1,1-dimethylhydrazine, tert-butylamine, or allylamine, a sulfur-containing precursor gas, such as hydrogen sulfide, an oxygen-containing precursor gas, such as H₂O, H₂O₂, O₂, O₃, or an alcohol, a phosphorous-containing precursor gas, such as phosphine gas or P(O)OMe₃, a hydrogen-containing has such as hydrogen gas, formalin, or a combination thereof. In any of the aspects or embodiments described herein, the second precursor gas can displace at least one ligand of the metal halide, the metal oxyhalide, the metal alkoxide, or a combination thereof. In an exemplary embodiment, the second precursor can displace at least one halogen of the metal halide. The second precursor gas can include an oxidant. The second precursor gas can include a reducing agent. In any of the aspects or embodiments described herein, the second precursor gas includes H₂O, H₂O₂, O₂, O₃, N₂O, NO, NO₂, NH₃, ammonia, 1,1-dimethylhydrazine, tert-butylamine, or allylamine, an alcohol, PH₃, P(O)OMe₃, hydrogen sulfide, H2, ambient air, formalin, or a combination thereof.

In any of the aspects or embodiments described herein, the first precursor gas includes palladium hexafluoro-acetylacetonate and the second precursor gas includes formalin. In any of the aspects or embodiments described herein, the first precursor gas includes bis(2,2,6,6-tetramethyl-3,5-heptanedionato)palladium(II)) and the second precursor gas includes ambient air.

In the disclosed methods, step b can be performed at least two times or from 2 to 4 times.

The methods are generally performed under vacuum pressure. The vacuum pressure is selected so that the first precursor gas is a solid or liquid (and not substantially vaporized) at room temperature. The first precursor can be heated to produce the first precursor gas. The second precursor can be heated to produce the second precursor gas. In an alternative embodiment, the second precursor gas is ambient air. The reactor can be opened to the atmosphere to expose the metal species precursor in the reactor to ambient air to oxidize the metal species precursor to the metal species. The method can include a combination of the foregoing.

The methods can include introducing an additional second precursor gas different from the second precursor gas introduced in step (b)(ii) of the disclosed methods. The additional second precursor gas can be used to convert a functional group attached to the metal of the metal species to a different functional group.

The methods can also include a purging step following step (b)(i), wherein the first precursor gas is introduced, following step (b)(ii), wherein the second gas is introduced, or a combination thereof. The purging can be performed using vacuum, using an inert gas, or a combination thereof. The purging step can remove unreacted precursor gases and by-products from the reaction of the first precursor gas with activated adsorbent material and/or the reaction of the second precursor gas with the metal species precursor deposited on the surface of the activated adsorbent material.

In any aspect or embodiment described herein, the method for preparing a modified activated adsorbent material comprises the steps: (a) providing an activated carbon in a reactor; (b) administering at least one atomic layer deposition cycle, wherein the administering at least one atomic layer deposition cycles comprises: (i) introducing TiCl₄ gas into the reactor; and (ii) introducing water vapor into the reactor to provide a titanium oxide modified activated carbon.

The activated carbon powder modified with titanium oxide has superior catalytic activity as compared with AEROXIDE® P25 TiO₂ (commercially available from Evonik, Hanau-Wolfgang, Germany) as determined according to 2-propanol temperature programmed desorption (TPD) spectra. For a more detailed description, see Yi Y. Wu, Harold H. Kung, Probing properties of the interfacial perimeter sites in TiOx/Au/SiO₂ with 2-propanol decomposition, Applied Catalysis A: General, Volume 548, 2017, Pages 150-163, which is incorporated by reference.

TPD of 2-propanol has been widely used to characterize oxide surfaces. It has been widely observed that 2-propanol will disproportionate on oxide surfaces, both dehydrogenating to acetone and dehydrating to propene. The catalytic activity of the deposited TiO₂ was characterized by comparing the yields of acetone and propene to those from P25.

In any of the described aspects or embodiments, an atomic layer deposition apparatus comprises a vacuum manifold, containers for each of the first precursor, the second precursor, and the activated carbon, a vacuum pump, a cold trap, at least one heat source, and a heating controller. The vacuum manifold includes lines with valves connected to the manifold for the first precursor gas, the second precursor gas, and the activated carbon substrate; containers for each of the first precursor, the second precursor, and the activated carbon substrate, each connected to the respective line of the manifold. The manifold and the containers can be heated for the efficient transfer of the precursor gases to the activated carbon.

In any of the described aspects or embodiments, the atomic layer deposition methods can be carried out in an apparatus suitable for batch mode, semi-continuous mode, continuous mode, or a combination thereof. In any of the aspects or embodiments described herein, the apparatus includes a fluidized bed reactor. It should be appreciated that the structures can be formed using any of apparatus known to one skilled in the art.

### EXAMPLES

Unless specifically indicated otherwise, the amount of each component is in weight percent (wt %), based on the total weight of the composition.

The bulk nitrogen to carbon, phosphorous to carbon, and oxygen to carbon ratios of the substrate may be measured using energy dispersive spectroscopy (EDS). EDS Spectra were provided by Elemental Analysis, Inc (Lexington, Ky.). Each sample was affixed to carbon tape. Spectra was obtained using an Oxford X-Max 80 Energy Dispersive Spectrometer at three different sites for each sample analyzed. The spectra were taken at 500× and 1,000× with an excitation voltage of 30 kV. Surface oxygen density may be measured using Boehm titration, Auger electron spectroscopy (AES), x-ray photoelectron spectroscopy (XPS), or low energy ion scattering (LEIS). Metal loading may be measured using Auger electron spectroscopy (AES), atomic absorption spectroscopy (AAS), energy dispersion spectroscopy (EDS), inductively coupled plasma spectroscopy (ICP), LEIS, or XPS.

### Example 1. ALD of TiO₂ on Activated Carbon Powder and Catalytic Characterization

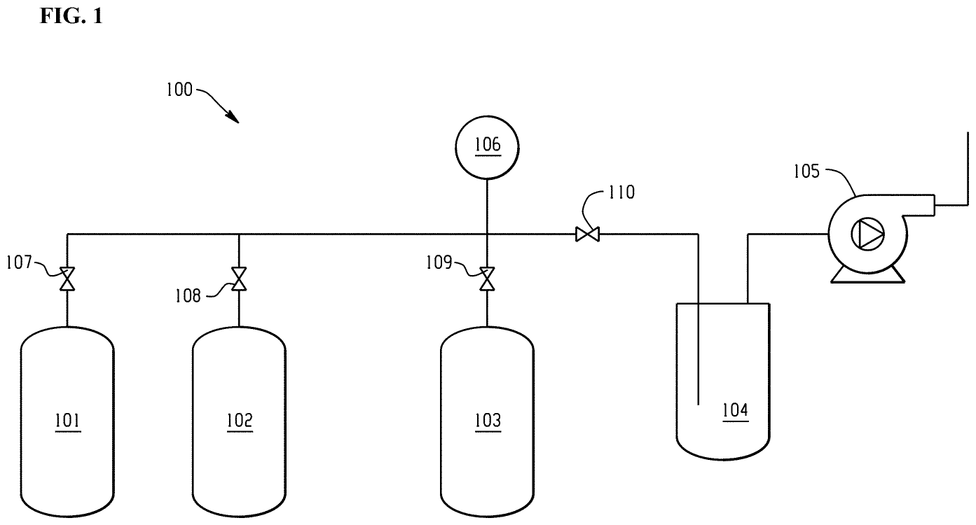

Example 1 describes ALD of TiO₂ on activated carbon powder and compares its performance to a TiO₂ powder. The activated carbon powder was NUCHAR® RGC (Ingevity South Carolina, LLC, N. Charleston, S.C., USA) and it had a d50 of 18.3 microns. The TiO₂ powder was AEROXIDE® P25 (Evonik, Hanau-Wolfgang, Germany) and it had a d50 of 2.95 microns. An ALD apparatus was constructed consistent with FIG. 1. The apparatus included a vacuum manifold, a cold trap (104), vacuum pump (105), and three source lines with valve controls (107, 108, 109). The three source lines were connected to the flasks (101, 102, and 103) for reaction precursors: the activated carbon, TiCl₄ (Titanium(IV) Chloride 99.9% from Sigma Aldrich), and oxidant (water). The manifold was covered in heating tape such that the manifold temperature was 200° C. Activated carbon (2 g) was charged to a flask, the flask was connected to the vacuum manifold, and the activated carbon was evacuated at 150° C. for 2 h at a vacuum pressure of about 10⁻³ torr to remove contaminants so that deposition of TiCl₄ and partial oxidation at active sites proceeded uninhibited. For example, if H₂O remained on the surface, TiCl₄ would likely oxidize/deposit in excess (CVD) and also not become anchored to the surface. The flask was allowed to cool to room temperature, removed from vacuum, and weighed to record loss in the weight. The flask was attached to the manifold and evacuated overnight at room temperature. TiCl₄ (5 mL) was added to a vial connected to the vacuum manifold. The vapor space in the vial was evacuated three times, allowing the contents of the vial to equilibrate in between vacuum pulses. TiCl₄ vapor (heated at 80° C.) was introduced to the reaction flask containing the activated carbon at 150° C. by opening valves 108, 109, and 110 such that the vacuum was less than 50 mTorr. Valve 110 was closed after 5 seconds. After 2 h, valve 108 was closed and valve 110 was slowly reopened. The reaction flask was evacuated for 2 h. The manifold was disconnected from the vacuum so that it was open to the air. The vial containing water was heated to 60° C. and valve 107, 109, and 110 were opened so that the humid air could flow over or through the reaction flask. After 2 hours, the heating was removed and the manifold was left open to the air overnight. The process was repeated 3 more times.

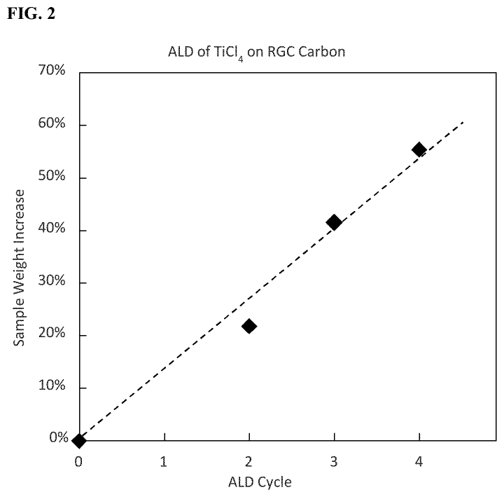

FIG. 2 shows the results of the gravimetric analysis of the activated carbon powder modified with titanium oxide after 1-4 cycles of ALD.

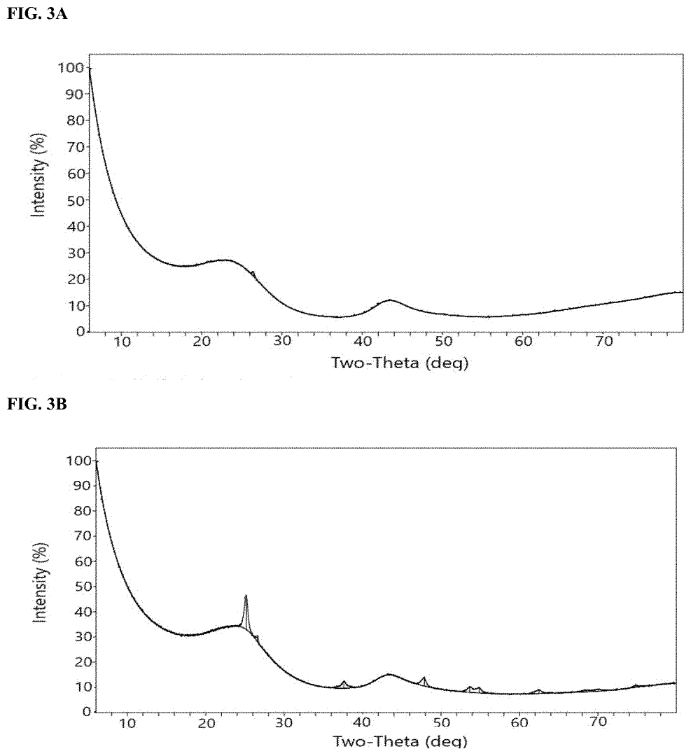

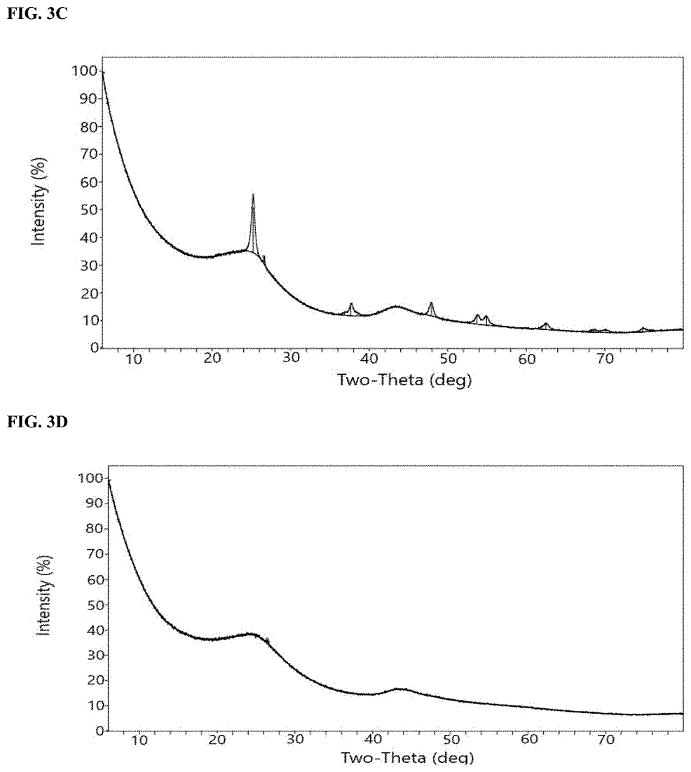

FIGS. 3A-3D show the wt % TiO₂ for activated carbon powder modified with titanium oxide after 0-4 cycles ALD.

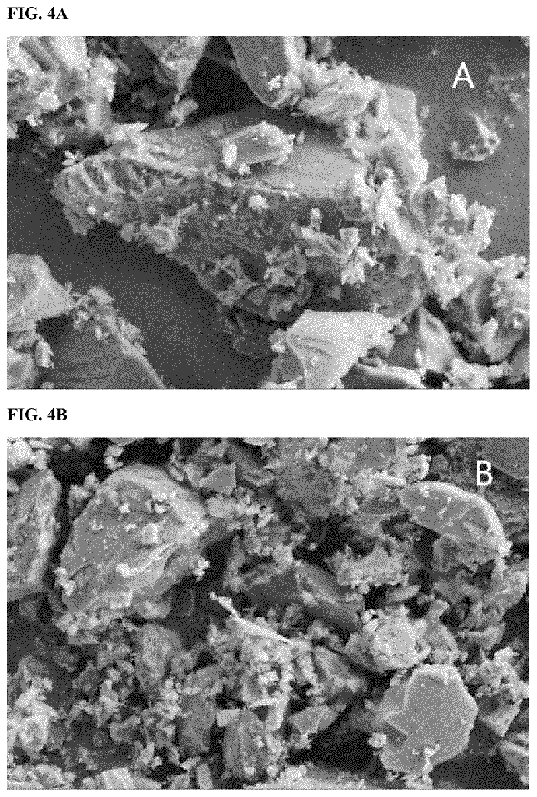

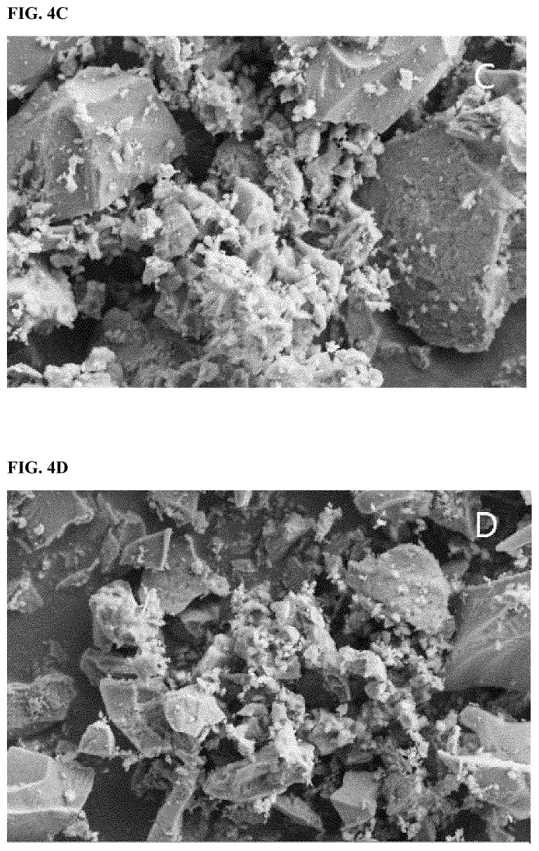

FIGS. 4A-4D are the SEM images of the activated carbon powder modified with titanium oxide after 0-4 cycles ALD.

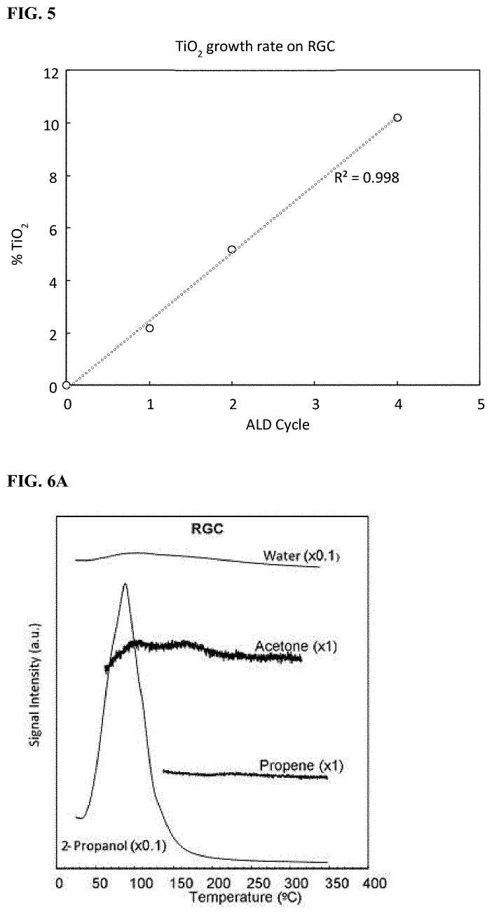

FIG. 5 shows the TiO₂ growth rate through 4 ALD cycles for the activated carbon powder modified with titanium oxide.

Characterization Method for TiO₂-modified RGC using Temperature-Programmed Desorption.

To characterize the catalytic activity of the TiO₂-modified RGC carbon samples, an in-house temperature-programmed desorption setup and technique was developed. The TPD setup consisted of a GC-MS (Shimadzu GCMS-QP2010S) connected to the exhaust port of a thermogravimetric analyzer (Perkin Elmer TGA 8000). The column in the GC-MS was bypassed to inject the exhaust gases directly into the GC-MS for real-time analysis of the TGA products. Samples were loaded into the TGA and saturated with 2-propanol. The 2-propanol saturated samples were maintained in 20 ml/min N₂ at 25° C. for 30 min to remove excess 2-propanol. The samples were heated at 10° C./min while simultaneously monitoring the desorption products with the GC-MS.

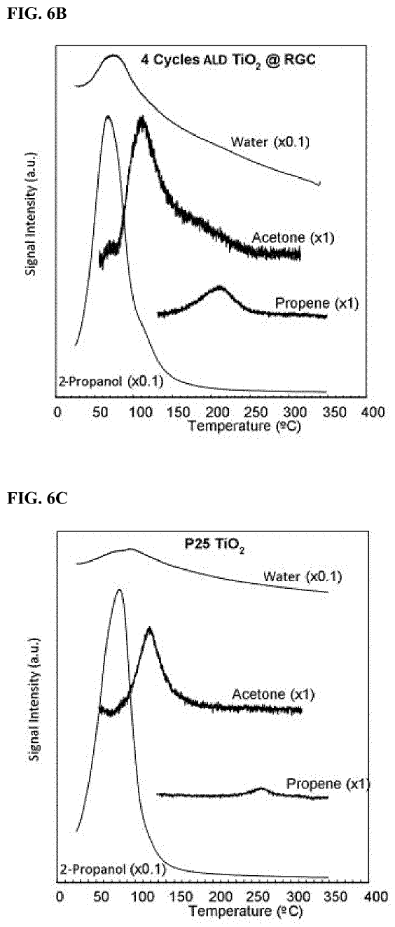

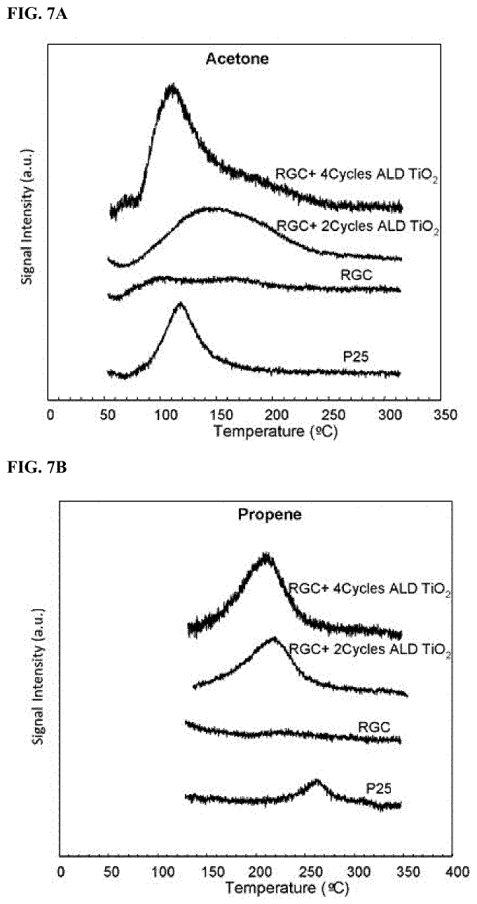

The TiO₂-modified RGC and commercially available P25 TiO2 were tested using the characterization methods described above. The 2-propanol temperature programmed desorption spectra (TPD spectra) of each are shown in FIGS. 6A-6C. The desorption peaks were integrated to quantify product yields. Desorption products were identified by their characteristic fragmentation patterns. Product yields were quantified using calculated mass spectrometer sensitivity factors. The characteristic masses (m/z) used to quantify the products from 2-propanol TPD were: 45 (2-propanol), 18 (H₂O), and 41 (propene). The product spectra comparison from the 2-propanol TPD are shown in FIG. 7A-7B. The acetone yield and propene yield from the TPD methods are summarized in Table 1 and show superior performance of TiO₂ modified RGC after 4 rounds of ALD.

TABLE 1

| Sample | Acetone yield (%) | Propene yield (%) |
|---|---|---|
| RGC | 0 | 0 |
| RGC after 2 cycles ALD (TiO₂) | 0.4 | 0.8 |
| RGC after 4 cycles ALD (TiO₂) | 8.1 | 1.1 |
| P25 TiO₂ | 2.9 | 0.2 |

### Example 2. ALD of TiO₂ on Granular Activated Carbon

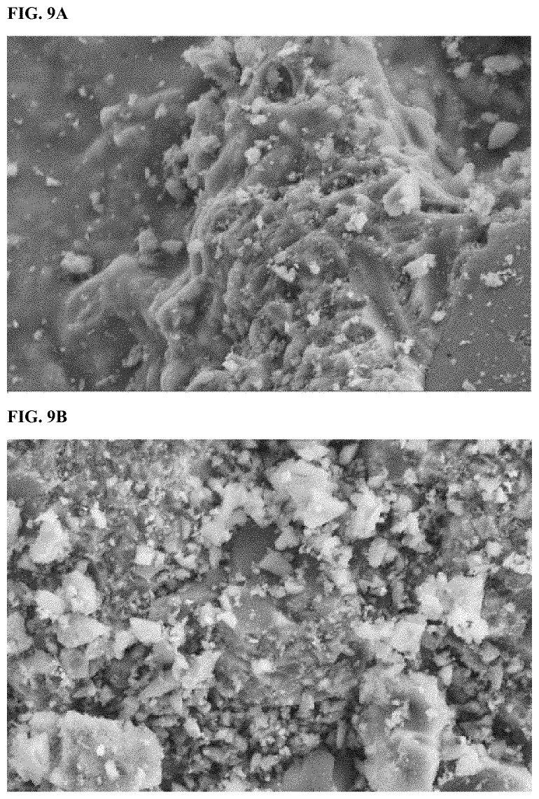

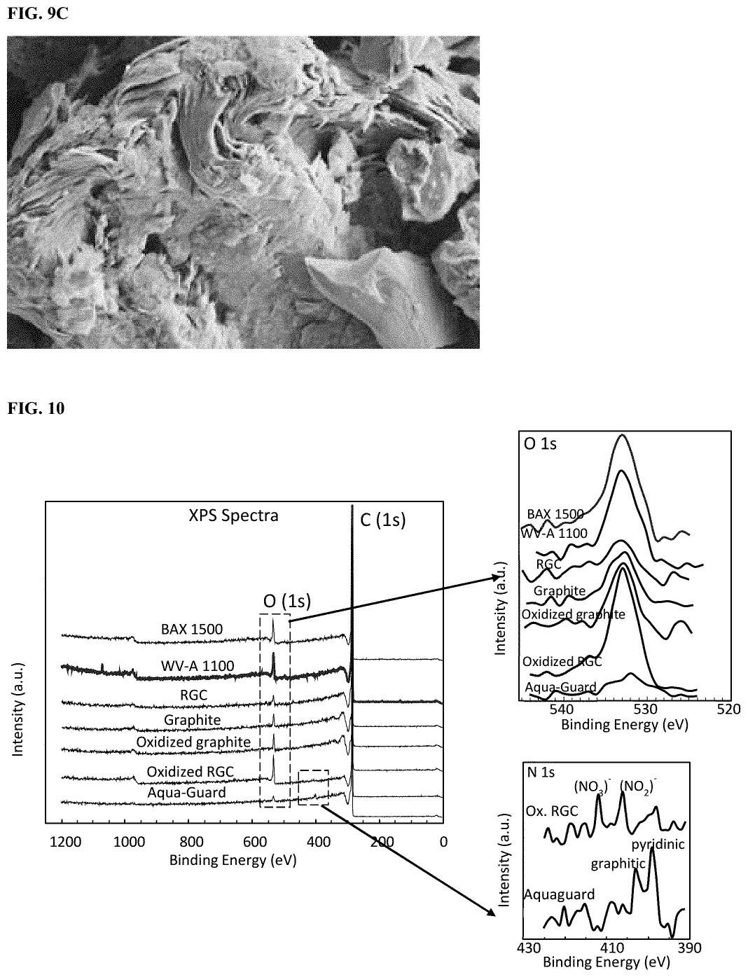

Example 2 describes ALD of TiO₂ on several activated carbons and graphite. The activated carbons and graphite were all screened to a particle size of 20×60 mesh. The activated carbons included NUCHAR® (Ingevity South Carolina LLC, N. Charleston, S.C., USA) chemically activated, wood-based carbons. These carbons were NUCHAR® RGC, NUCHAR® AquaGuard (AG), NUCHAR® BAX 1500, and NUCHAR WV-A 1100. A thermally activated, coconut-based carbon (20×50 mesh, acid washed, 85-90 CTC (Carbon Activated Corp, Compton, Calif., USA)_and a graphite (SAG20 (MTI Corporation, Richmond, Calif., USA)) were also used. For tests with oxidized samples, the graphite and RGC were both oxidized by placing the respective carbon in a beaker containing 70% Nitric Acid (Sigma-Aldrich). The carbon to nitric acid ratio was 1:10. The beaker containing the acid and carbon was heated to 80° C. and then agitated for 3 hours. The carbon was then removed from the acid using vacuum filtration. The filtered carbon was washed using distilled water until the pH was >5. The carbon was then placed in a 110° C. oven overnight. Table 2 shows BET surface area and pore volume for each of these carbons. Prior to subjecting the carbons to ALD, the carbons were analyzed by XPS for C, O, N, and P content and the results are shown in FIG. 10 and summarized in Table 3. FIGS. 9A-9C show SEM images of virgin WV-A1100 (FIG. 9A), BAX1500 (FIG. 9B), and graphite (FIG. 9C).

TABLE 2

| Sample | BET Surface Area (m²/g) | Pore volume to 320 Å (cm³/g) |
|---|---|---|
| RGC | 1573 | 1.12 |
| WV-A1100 | 1678 | 1.14 |
| Oxidized RGC | 1415 | 1.07 |
| AquaGuard | 1716 | 1.34 |
| BAX1500 | 1898 | 1.11 |
| Coconut | 1405 | 0.64 |
| Graphite | ND | ND |

*ND = not detectable

TABLE 3
XPS Results (atomic %)

| | Aqua- | BAX | Oxidized | | Oxidized | | WVA | |
|---|---|---|---|---|---|---|---|---|
| Element | Guard | 1500 | Graphite | Graphite | RGC | RGC | 1100 | Coconut |
| Carbon | 94.6 | 89.5 | 95.6 | 96.2 | 85.3 | 97.1 | 93.7 | 95.5 |
| Oxygen | 2.8 | 10 | 4.4 | 3.8 | 13.5 | 2.9 | 5.8 | 4.5 |
| Nitrogen | 2.6 | ND | ND | ND | 1.2 | ND | ND | ND |
| Phosphorous | ND | 0.5 | ND | ND | ND | ND | 0.5 | ND |

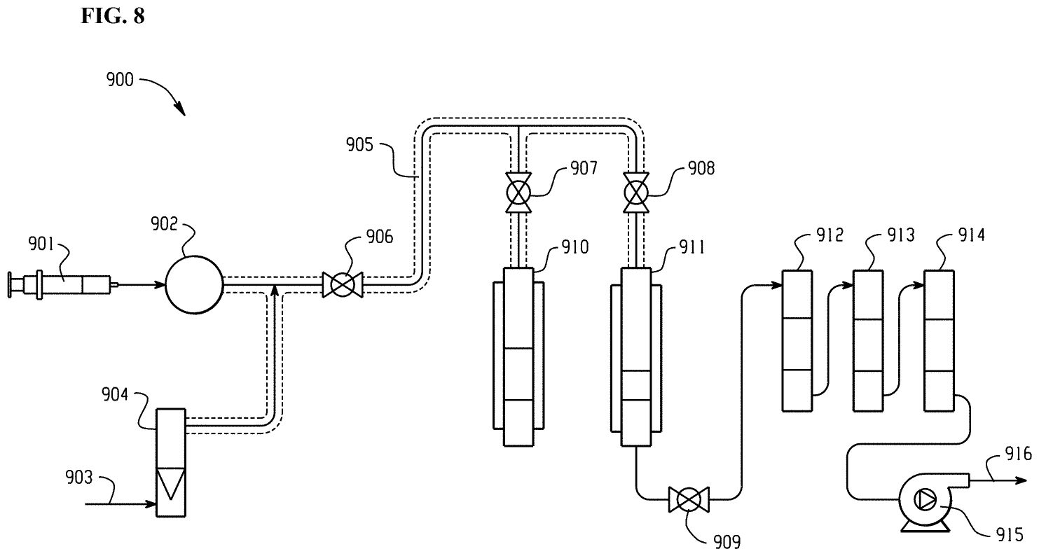

An ALD apparatus was constructed consistent with FIG. 8. The apparatus included heated source lines with valve controls in-line with a vacuum pump. To generate humid air, a source line was connected to a steam generator which was connected to a syringe filled with water. Air was introduced into the heated trace line. As shown in FIG. 8, TiCl₄ was present in one column and carbon was present in a second column. Prior to deposition, the apparatus was evacuated overnight under a vacuum pressure of about 10⁻³ torr at room temperature by closing valve 906 and opening valves 908 and 909. The traced lines were heated to 200° C. and the column containing the TiCl₄ and the column containing the carbon were heated to 80° C. and 150° C., respectively. To deposit TiCl₄ on carbon, valve 909 was closed and 907 and 908 were opened for 2 h. After 2 h, valve 907 was closed and valve 909 was slowly reopened. The apparatus was evacuated for 2 h. Then valve 906 was opened so that the humid air could flow through the carbon column. After 2 hours, the heating was removed and the manifold was left open to the air overnight. The process was repeated once more, but can be repeated 2-4 times.

After two cycles of ALD with TiO₂, the estimated surface coverage was calculated assuming monolayer coverage according to the formula below. (e.g., rho and a).

$$\% Coverage = \frac{W t \% {TiO}_{2}}{{ρ}_{{TiO}_{2}} \cdot a} \cdot \frac{1}{Carbon S . A .}$$

Where ρ_{TiO2} is the bulk density (m3/g) of TiO₂, Carbon S.A. is the BET Surface Area (m2/g) and α is the characteristic length of the unit cell of TiO₂ (lattice parameter, m).

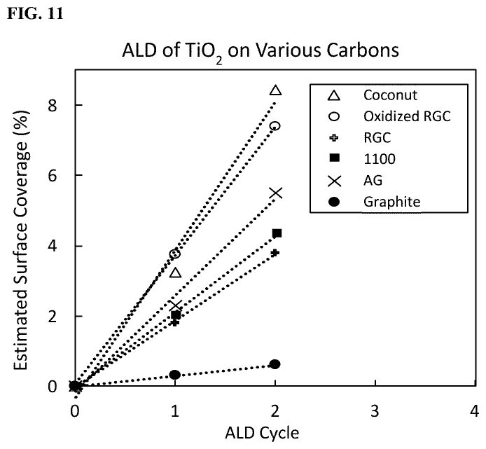

FIG. 11 shows a comparison of the estimated surface coverage for coconut, oxidized RGC, RGC, WVA1100, AquaGuard (AG), and graphite after varying ALD cycles. For the estimates presented in this figure, it is assumed that TiO₂ is deposited as rutile-phase. This figure shows that the rate of TiO₂ ALD was greatest for coconut and follows the order: coconut>oxidized RGC, Aquaguard, WV-A 1100 RGC>Graphite. In addition, surface oxidation enhanced the deposition rate of TiO₂ (compare oxidized RGC to RGC).

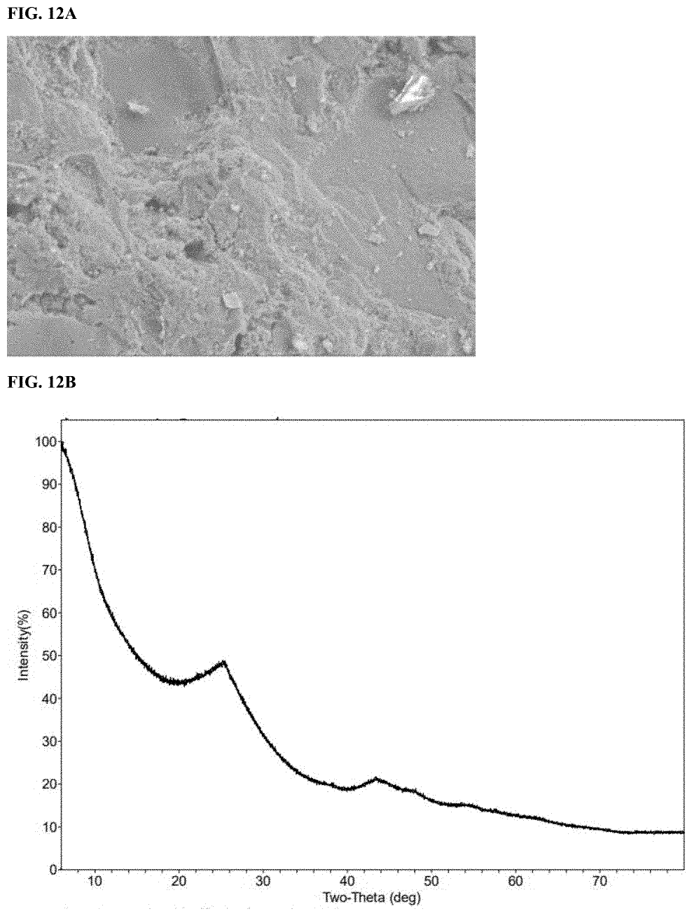

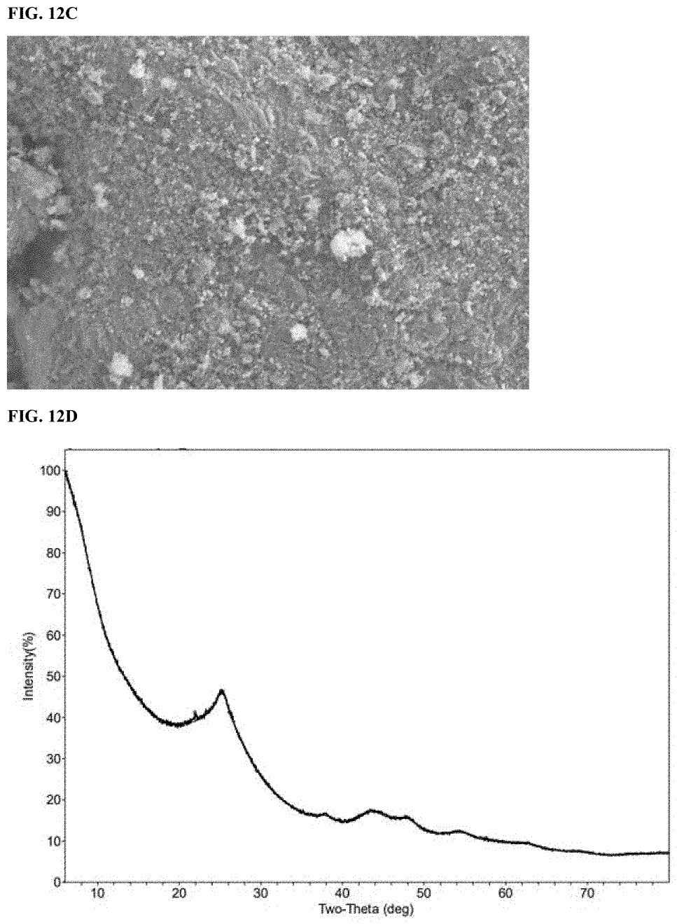

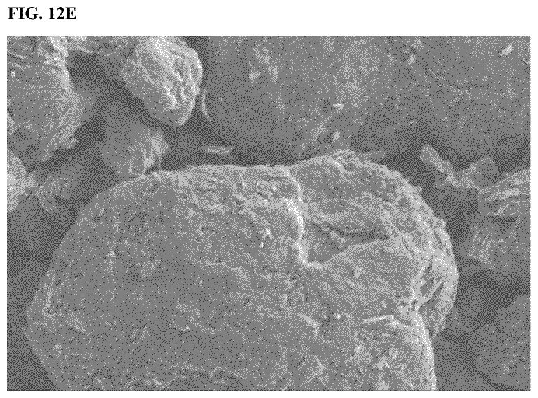

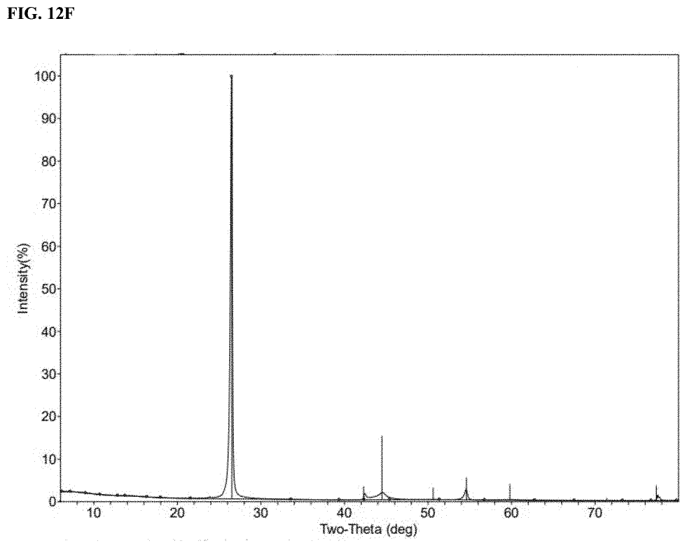

FIGS. 12A-12F shows the SEM photographs and XRD of oxidized RGC, AG, and graphite after two cycles of TiO₂ ALD. Oxidized RGC had higher incorporation of TiO₂ as compared with AG (non-oxidized). Graphite had very poor TiO₂ incorporation.

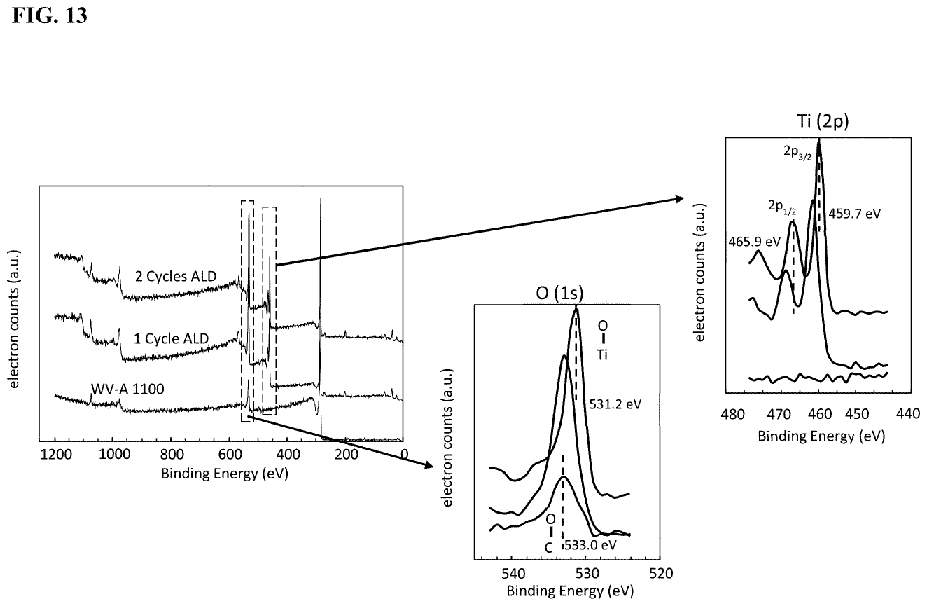

FIG. 13 shows the XPS spectrum of WV-A 1100 before and after TiO₂ ALD. The virgin material is the bottom trace, the material after one cycle of ALD is the middle trace and the material after two cycles of ALD is the top trace.

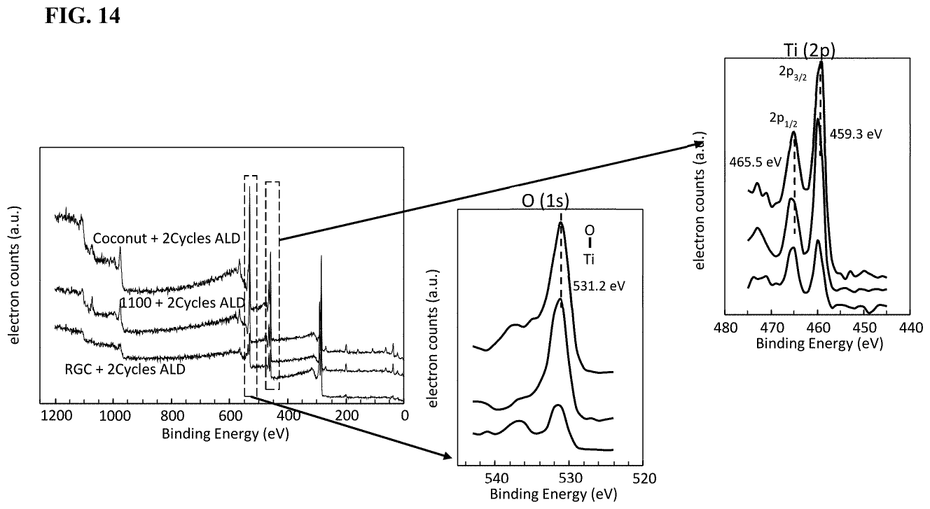

FIG. 14 shows the XPS spectra of coconut, 1100, and RGC, each after two cycles of TiO₂ ALD. The RGC after two cycles of ALD is the bottom trace, the 1100 after two cycles of ALD is the next highest trace, and coconut after two cycles of ALD is the top trace. The O1s peak corresponds to a metal oxide. The Ti(2p) peaks at 2p3/2 and 2p1/2 correspond to the Ti atom being well oxidized (TiO₂ formation).

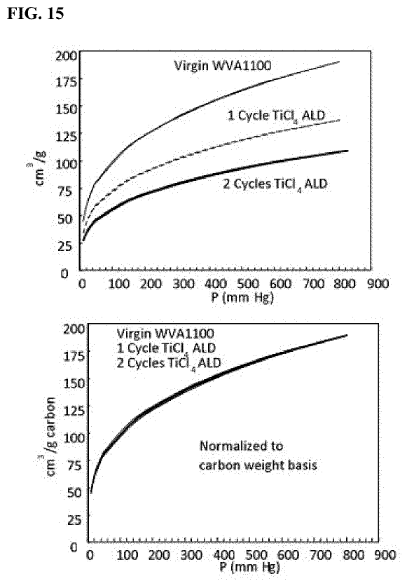

FIG. 15 shows the butane isotherm results for WVA1100 before and after TiO₂ ALD. FIG. 15A shows the isotherm results based on the total weight of the sample. The virgin material is the top trace, the material after one cycle of ALD is the middle trace and the material after two cycles of ALD is the bottom trace. After normalizing by the weight basis of carbon, there is substantial overlap of the plots for the virgin, one-cycle and two-cycle materials as shown in FIG. 15B.

### Example 3. Catalytic Characterization of TiO₂-Modified Granular Carbons Using Temperature-Programmed Desorption (TPD)

In order to test the catalytic activity of the TiO₂-modified carbon samples, an in-house desorption setup and technique was developed. The TPD setup included a GC-MS (SHIMADZU GCMS-QP2010S) connected to the exhaust port of a thermogravimetric analyzer (PERKIN ELMER TGA 8000). The column in the GC-MS was bypassed to inject the exhaust gases directly into the mass spectrometer for real-time analysis of the TGA products. The samples were loaded into the TGA and saturated with 2-propanol. Nitrogen (g) was passed at 20 mL/min at 25° C. for 30 min to remove excess 2-propanol and heated at 10° C./min while simultaneously monitoring the desorption products with the mass spectrometer. The desorption products were identified by their characteristic fragmentation patterns. Product signal were corrected by their sensitivity factors. The characteristic masses (m/z) used to quantify products from 2-propanol were: 45 (2-propanol), 18 (H₂O), and 41 (propene).

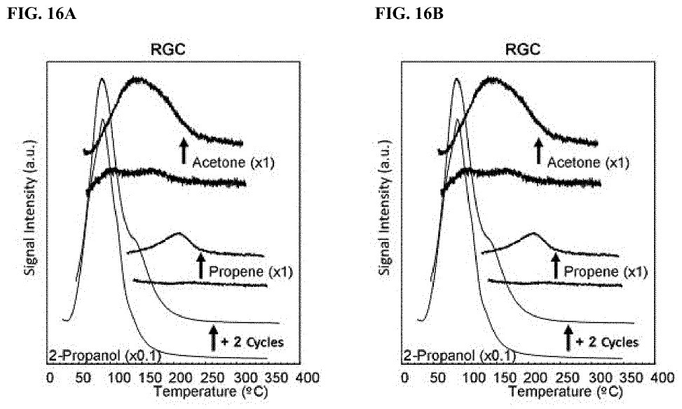

FIGS. 16A-16B show the TPD spectra after two cycles of TiO₂-ALD for WV-A1100 and RGC, respectively. For each of FIGS. 16A-16B, the spectrum of the ALD-modified material is overlayed with that of the virgin material. The lower curves for acetone, CO₂, and propene are for the material that has been subjected to one cycle of ALD and the upper curve for each of acetone, CO₂, and propene after a second cycle of ALD.

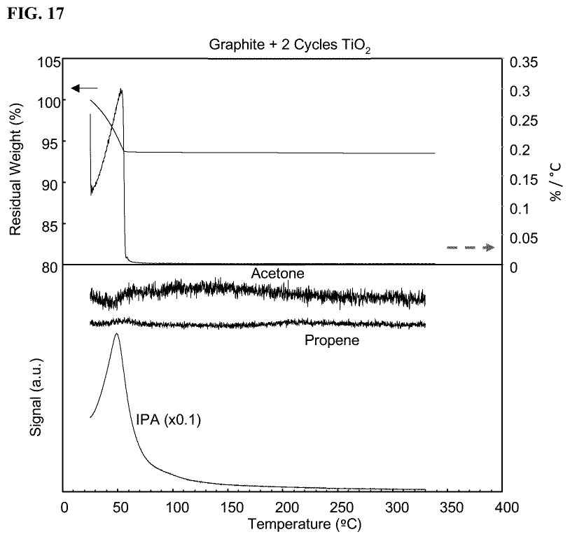

FIG. 17 shows the TPD spectrum of TiO₂-modified graphite. No reaction products were detected and rapid desorption was observed due to the lack of porosity of the material.

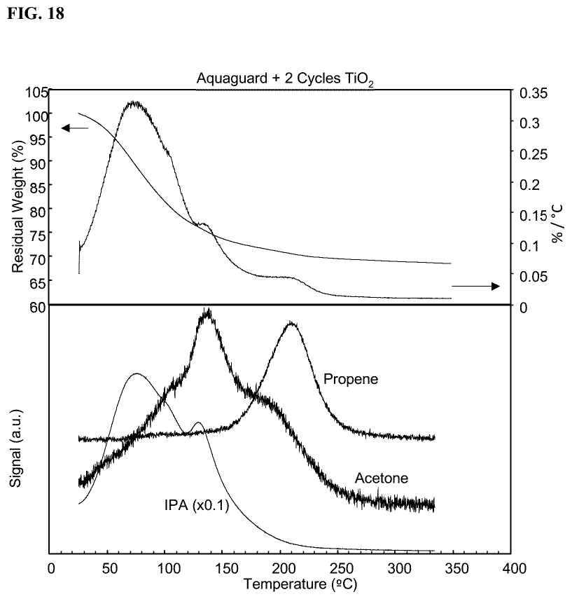

FIG. 18 shows the TPD spectrum of TiO₂-modified AQUAGUARD. The peak at 120 indicates a reactive intermediate wherein the oxygen of 2-propanol is bound to Titanium.

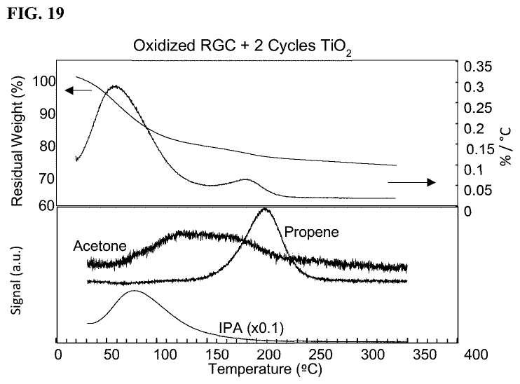

FIG. 19 shows the TPD spectrum of TiO₂-modified oxidized RGC. The acetone and propene reaction products were detected.

### Example 4. Palladium Deposition on WV-A 1100

Pd deposition was performed using palladium hexafluoro-acetylacetonate as the first precursor gas. The carbon sample was placed in the sample column with sample oven set to 110° C. and line heaters set to 180° C. and evacuated for 2 hours. The sample oven and line heaters were allowed to cool to 70° C. Palladium hexafluoro-acetylacetonate was added to the sample column. Vacuum pressure was reestablished for 2 minutes by opening valve 909. At this point, valve 909 was closed and the precursor deposition allowed to take place for 30 minutes. After the deposition, valve 909 was reopened and the sample was evacuated using the following temperature ranges and times: (1) deposit at 70° C. for 30 min, (2) evacuate at 70° C. for 30 min, 110° C. for 30 min, 180° C. for 2 h. Line heaters were heated to 180° C. and sample oven was allowed to remain at 180° C. The sample column was then opened to the atmosphere by opening valves 906 and 908 and, using a nitrogen flow set to 500 sccm, 37% formalin (second precursor gas) was pumped through the steam generator. This formalin was pumped through the system for an hour. Once finished, the sample was removed and placed in a 110° C. oven overnight.

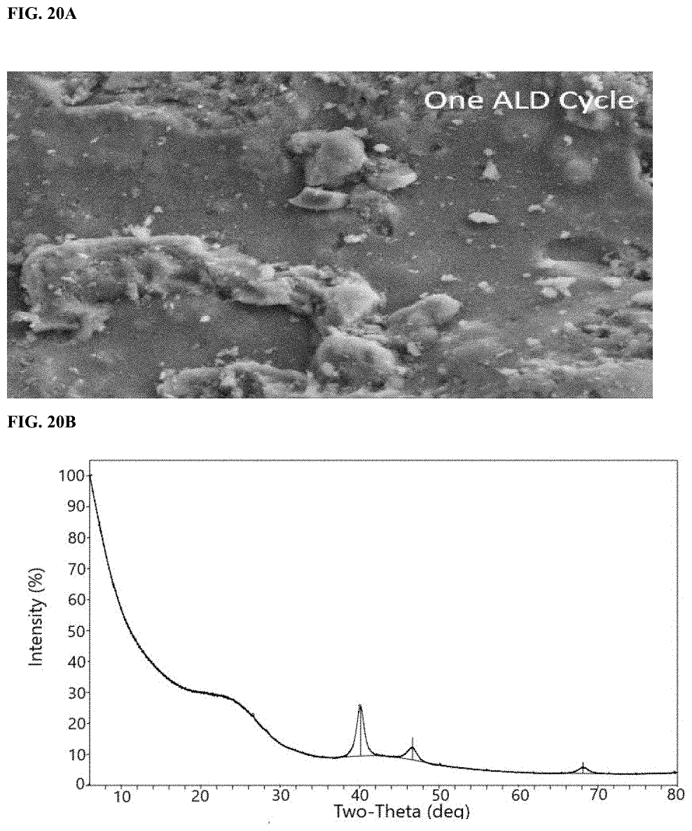

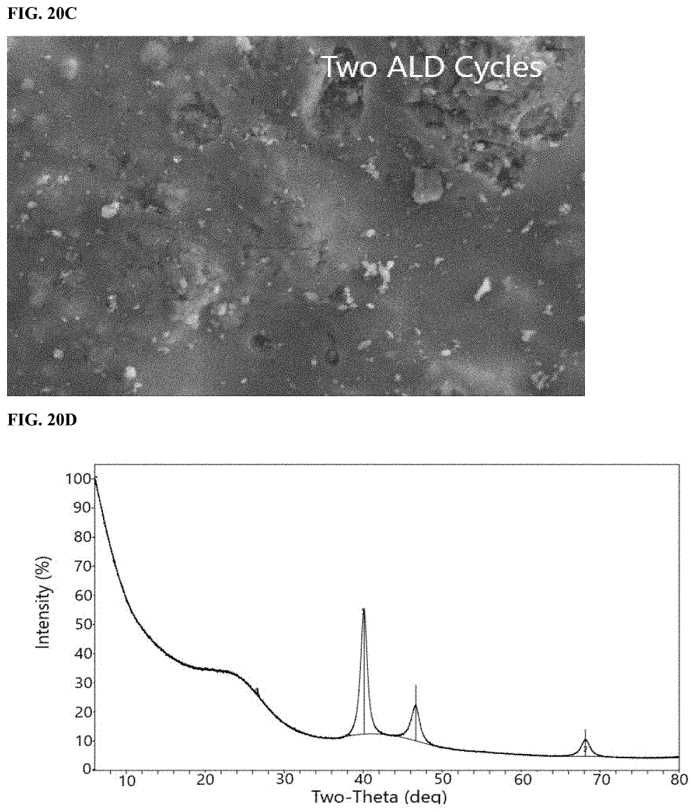

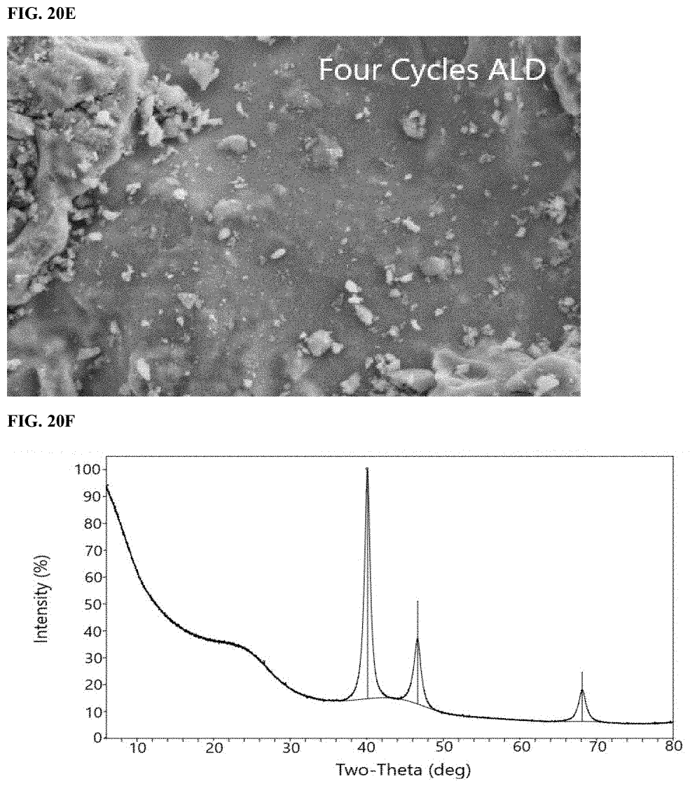

FIGS. 20A-20F shows the SEM photographs and XRD of WV-A 1100 after one cycle of Pd ALD (FIGS. 20A-20B), two cycles of ALD (FIGS. 20C-20D), and four cycles of ALD (FIGS. 20E-20F).

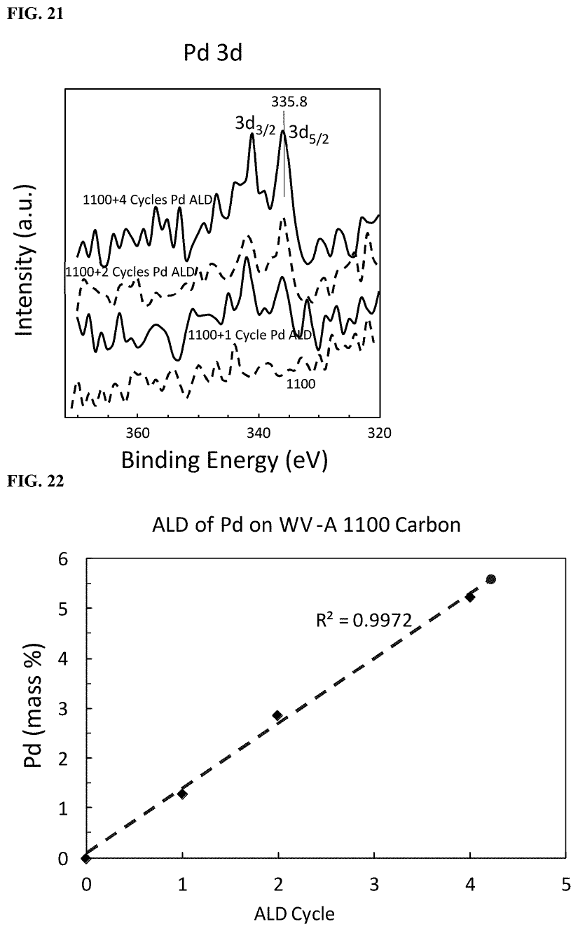

FIG. 21 shows the XPS of Pd-modified samples of WV-A 1100 after 1, 2, and 4 cycles of ALD. The bottom trace is the virgin material, the next trace above is after 1 cycles of ALD, the next trace above is after 2 cycles of ALD, and the top trace is after 4 cycles of ALD. The peak at 339.8 corresponds to Pd. It is apparent the peak at 335.8 eV increases with the number of ALD cycles.

FIG. 22 shows the wt % of Pd deposited on WV-A 1100 after 1 cycle (1.29 wt %), 2 (2.84 wt %), and 4 cycles (5.21 wt %) of ALD.

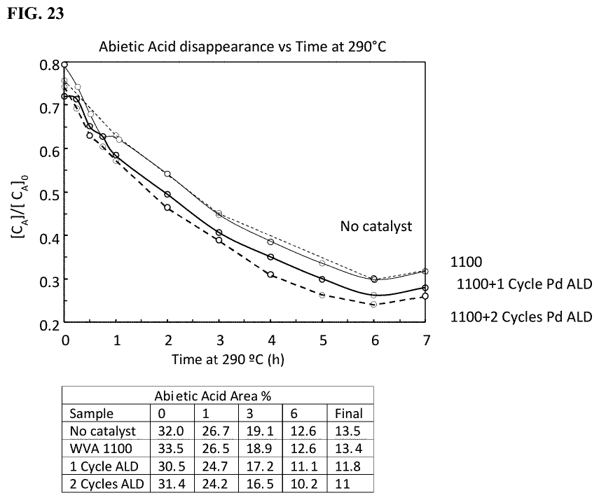

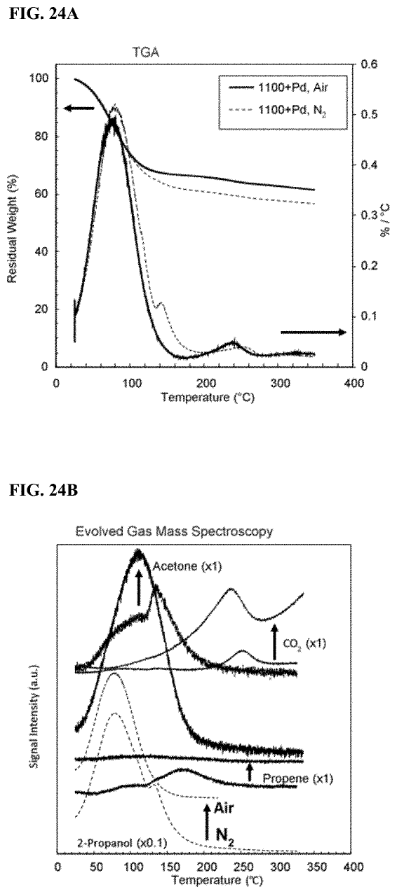

The activity of the catalyst was tested in a reaction with abietic acid. Abietic acid has been shown to readily convert to dehydroabietic acid in the presence of conventional Pd catalysts (Linlin Wang, Xiaopeng Chen, Wenjing Sun, Jiezhen Liang, Xu, Zhangfa Tong, Kinetic model for the catalytic disproportionation of pine oleoresin over Pd/C catalyst, Industrial Crops and Products, Volume 49, 2013, pp. 1-9). The catalytic activity of the deposited Pd was characterized by evaluating the rate of abietic acid disappearance and the corresponding rate of dehydroabietic acid formation FIG. 23 shows the disappearance of abietic acid over time. The two overlapping curves are the reaction without catalyst and the virgin material. The bottom curve corresponds to the reaction of abietic acid in the presence of the Pd-modified material (i.e., catalyst) obtained after 2 cycles of ALD. The curve above corresponds to the reaction of abietic acid in the presence of the Pd-modified material (i.e., catalyst) obtained after 1 cycle of ALD.

The activity of the catalyst (i.e., Pd deposited on WV-A 1100) was tested in an alcohol dehydrogenation reaction with 2-propanol. FIG. 24A shows the TGA spectrum using air and N2. FIG. 24B shows the evolved gas spectrum.

### Example 5. Palladium Deposition on Other Carbons

Pd deposition was performed as described in Example 4.

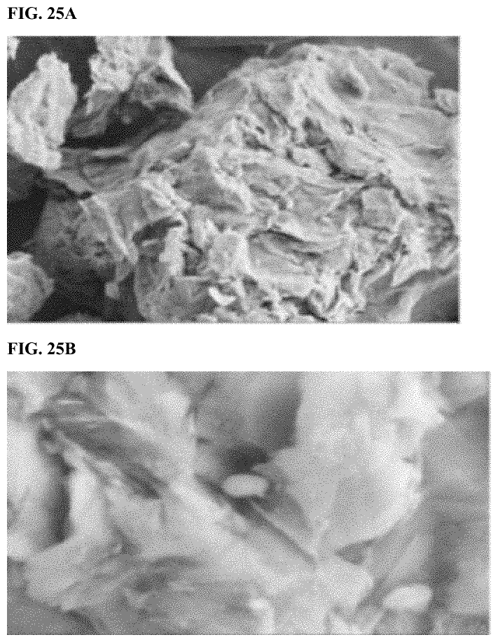

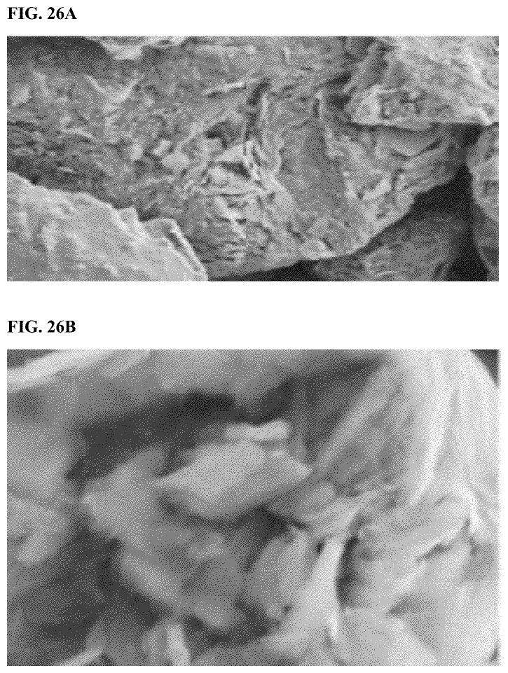

FIG. 25A shows SEM photographs of graphite after 2 cycles of Pd ALD at 10,000× magnification. FIG. 25B shows SEM photographs of graphite after 2 cycles of Pd ALD at 100,000× magnification.

FIG. 26A shows SEM photographs of oxidized graphite after 2 cycles of Pd ALD at 10,000× magnification. FIG. 26B shows SEM photographs of graphite after 2 cycles of Pd ALD at 100,000× magnification.

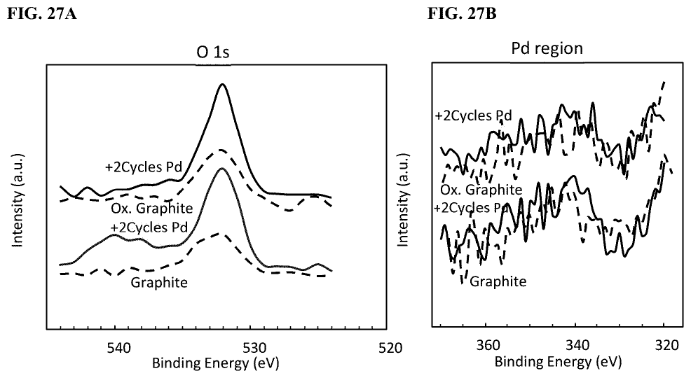

FIGS. 27A-27B shows the XPS of graphite and oxidized graphite before and after 2 cycles of ALD. The bottom trace is the virgin graphite and the trace above is after the second cycle of ALD (FIG. 27A). Similarly, the trace above that is the virgin oxidized graphite and the trace above is after the second cycle of ALD (FIG. 27A). FIG. 27B shows that there is no peak in the region corresponding to Pd. The lack of a detected Pd peak shows that the deposition of Pd via ALD on both oxidized graphite and graphite was unsuccessful.

PIXE analysis of Pd-modified carbon samples is summarized in Table 4 below.

TABLE 4

| Sample | wt % Pd |
|---|---|
| Graphite + 1 Cycle Pd ALD | 0.05 |
| Graphite + 2 Cycles Pd ALD | 0.07 |
| Oxidized Graphite + 1 Cycle Pd ALD | 0.02 |
| Oxidized Graphite + 2 Cycles Pd ALD | 0.07 |
| RGC + 2 Cycles Pd ALD | 2.00 |
| Oxidized RGC + 2 Cycles Pd ALD | 3.57 |
| AG + 2 Cycles Pd ALD | 2.21 |
| WV-A 1100 + 2 Cycles Pd ALD | 2.84 |

What is claimed is:

1. A structure comprising a substrate comprising an activated adsorbent material and a metal species deposited thereon.

2. The structure of claim 1, wherein the metal species deposited thereon is a film, layer, or coating.

3. The structure of claim 1, wherein other than activation, the activated adsorbent material is not additionally modified.

4. The structure of claim 1, wherein the activated adsorbent material comprises activated carbon, carbon charcoal, nanostructured carbon, expanded graphite, graphene, zeolites, clays, porous polymers, porous alumina, porous silica, molecular sieves, kaolin, titania, ceria, or a combination thereof.

5. The structure of claim 1, wherein the activated adsorbent material comprises an activated carbon in a powder, granular, pellet, monolith, or honeycomb form.

6. The structure of claim 5, wherein the activated carbon is derived from at least one of wood, wood dust, wood flour, cotton linters, peat, coal, coconut, lignite, carbohydrates, petroleum pitch, petroleum coke, coal tar pitch, fruit pits, fruit stones, nut shells, nut pits, sawdust, palm, vegetables, a synthetic polymer, natural polymer, lignocellulosic material, or a combination thereof.

7. The structure of claim 5, wherein the activated carbon is activated using an activating comprising at least one of phosphoric acid, sulfuric acid, boric acid, nitric acid, oxygenated acids, steam, air, peroxides, alkali hydroxides, metal chlorides, ammonia, carbon dioxide, or a combination thereof.

8. The structure of claim 1, wherein the activated adsorbent material is characterized by a mesoporous pore size, macroporous pore size, or a combination thereof.

9. The structure of claim 1, wherein the activated adsorbent material is characterized by a nitrogen B.E.T. surface area from about 600 to about 2500, or from about 800 to about 1800, or about 1000 to about 1600 squared meters per gram.

10. The structure of claim 1, wherein the activated carbon has a bulk oxygen to carbon ratio at a depth less than 5 nm of less than or equal to about 0.25.

11. The structure of claim 5, wherein the activated carbon has a bulk phosphorous to carbon ratio at a depth less than 5 nm of less than or equal to about 0.10.

12. The structure of claim 5, wherein the activated carbon has a bulk nitrogen to carbon ratio at a depth less than 5 nm of less than or equal to about 0.15.

13. The structure of claim 5, wherein the activated carbon has a surface oxygen to carbon ratio of less than or equal to about 1, based on the total number of surface carbons.

14. The structure of claim 5, wherein the activated carbon has a surface phosphorous to carbon ratio of less than or equal to about 0.33, based on the total number of surface carbons.

15. The structure of claim 5, wherein the activated carbon has a surface nitrogen to carbon ratio of less than or equal to about 0.5, based on the total number of surface carbons.

16. The structure of claim 5, wherein the activated carbon has a surface oxygen of oxidized phosphorous to phosphorous ratio of less than or equal to about 1.0, based on the total number of surface phosphorous atoms.

17. The structure of claim 1, wherein the metal species is derived from a metal species precursor comprising at least one metal and at least one ligand.

18. The structure of claim 1, wherein the metal species comprises a metal, a metal oxide, a metal oxide phosphate, a multi-metal oxide, a perovskite, a metal sulfide, a metal nitride, a metal phosphide, an organometallic compound, or a combination thereof.

19. The structure of claim 1, wherein the metal species comprises titanium oxide.

20. The structure of claim 1, wherein the metal species comprises palladium.

21. The structure of claim 1, wherein the structure comprises from about 0.5 to about 50 wt % of the metal species, based on the total weight of the structure.

22. A method for preparing a structure according to the steps comprising:
a. providing an activated adsorbent material in a reactor;
b. administering at least one atomic layer deposition cycle to deposit a metal species, wherein the administering at least one atomic layer deposition cycle comprises:
i. introducing a first precursor gas into the reactor to provide a metal species precursor deposited on a surface of the activated adsorbent material;
ii. introducing a second precursor gas into the reactor to provide the structure.

23. The method of claim 22, wherein step b is performed 2 to 10 times.

24. The method of claim 22, further comprising a step after step (b)(i), after step (b)(ii), or a combination thereof comprising purging the reactor.

25. The method of claim 22, wherein the activated adsorbent material comprises activated carbon, carbon charcoal, nanostructured carbon, expanded graphite, graphene, zeolites, clays, porous polymers, porous alumina, porous silica, molecular sieves, kaolin, titania, ceria, or a combination thereof.

26. The method of claim 22, wherein the first precursor gas comprises at least one metal and at least one ligand.

27. The method of claim 22, wherein the first precursor gas comprises a metal halide, a metal oxyhalide, an organometallic compound, or a combination thereof.

28. The method of claim 22, wherein the second precursor gas is capable of displacing a ligand of the metal species precursor deposited on the surface of the activated adsorbent material.

29. The method of claim 22, wherein the second precursor gas comprises H₂O, H₂O₂, O₂, O₃, N₂O, NO, NO₂, NH₃, ammonia, 1,1-dimethylhydrazine, tert-butylamine, or allylamine, an alcohol, PH₃, P(O)OMe₃, hydrogen sulfide, H₂, ambient air, formalin, or a combination thereof.

30. The method of claim 22, wherein the activated adsorbent material is derived from at least one of wood, wood dust, wood flour, cotton linters, peat, coal, coconut, lignite, carbohydrates, petroleum pitch, petroleum coke, coal tar pitch, fruit pits, fruit stones, nut shells, nut pits, sawdust, palm, vegetables, a synthetic polymer, natural polymer, lignocellulosic material, or a combination thereof.

31. The method of claim 22, wherein the activated adsorbent material is characterized by a nitrogen B.E.T. surface area from about 600 to about 2500, or from about 800 to about 1800, or about 1000 to about 1600 squared meters per gram.

32. The method of claim 22, wherein the absorbent material comprises activated carbon in a powder, granular, pellet, monolith, or honeycomb form.

33. The method of claim 32, wherein the activated carbon has a bulk oxygen to carbon ratio at a depth less than 5 nm of less than or equal to about 0.25.

34. The method of claim 32, wherein the activated carbon has a bulk phosphorous to carbon ratio at a depth less than 5 nm of less than or equal to about 0.10.

35. The method of claim 32, wherein the activated carbon has a bulk nitrogen to carbon ratio at a depth less than 5 nm of less than or equal to about 0.15.

36. The method of claim 32, wherein the activated carbon has a surface oxygen to carbon ratio of less than or equal to about 1.0, based on the total number of surface carbons.

37. The method of claim 32, wherein the activated carbon has a surface phosphorous to carbon ratio of less than or equal to about 0.33 based on the total number of surface carbons.

38. The method of claim 32, wherein the activated carbon has a surface nitrogen to carbon ratio of less than or equal to about 0.5, based on the total number of surface carbons.

39. The method of claim 32, wherein the activated carbon has a surface oxygen of oxidized phosphorous to phosphorous ratio of less than or equal to about 1.0, based on the total number of surface phosphorous atoms.

40. The method of claim 32 comprising:
a. providing an activated carbon powder in a reactor;
b. administering at least one atomic layer deposition cycle to deposit the metal species comprising titanium oxide, wherein the administering at least one atomic layer deposition cycles comprises:
i. introducing TiCl₄ gas into the reactor to provide titanium chloride deposited on a surface of the activated carbon powder;
ii. introducing water vapor or ambient air into the reactor to provide the titanium oxide deposited on the surface of the activated carbon powder.

41. The method of claim 22, wherein at least one of:
a. the activated adsorbent material is an activated carbon powder;
b. the metal species comprises palladium;
c. the first precursor gas is palladium hexafluoro-acetylacetone;
d. the second precursor gas is formalin or ambient air; or
e. a combination thereof
i.

42. A method of comprising:
a. providing an activated carbon powder in a reactor;
b. administering at least one atomic layer deposition cycle to deposit a metal species comprising palladium, wherein the administering at least one atomic layer deposition cycle comprises:
i. introducing bis(2,2,6,6-tetramethyl-3,5-heptanedionato)palladium(II) into the reactor to provide a palladium intermediate deposited on a surface of the activated carbon powder; and
ii. introducing ambient air into the reactor to provide the palladium deposited on the surface of the activated carbon powder.
